(19) United States
(12) Patent Application Publication
(10) Pub. No.: US 2023/0215826 A1
(43) Pub. Date: Jul. 6, 2023

(54) SEMICONDUCTOR DEVICE AND DATA STORAGE SYSTEM INCLUDING THE SAME

(71) Applicant: Samsung Electronics Co., Ltd., Suwon-si (KR)

(72) Inventor: Jihong KIM, Seongnam-si (KR)

(73) Assignee: Samsung Electronics Co., Ltd., Suwon-si (KR)

(21) Appl. No.: 18/147,501

(22) Filed: Dec. 28, 2022

(30) Foreign Application Priority Data
Dec. 30, 2021 (KR) 10-2021-0193035
Jan. 21, 2022 (KR) 10-2022-0009407

(51) Int. Cl. H01L 23/00; H01L 25/065; H01L 25/18

(52) U.S. Cl. CPC H01L 24/08; H01L 25/0657; H01L 25/18; H01L 2224/08145; H01L 2924/1431; H01L 2924/1441; H01L 2924/1443; H01L 2924/1444; H01L 2924/14511

(57) ABSTRACT

A semiconductor device includes a first non-volatile memory structure including a first stack structure including first conductive lines stacked and spaced apart from each other and a first vertical memory structure penetrating through the first stack structure; a second non-volatile memory structure including a second stack structure including second conductive lines stacked and spaced apart from each other and a second vertical memory structure penetrating through the second stack structure; and a peripheral circuit structure electrically connected to the first and second non-volatile memory structures. The peripheral circuit structure, the first non-volatile memory structure, and the second non-volatile memory structure vertically overlap each other. The first vertical memory structure includes a first data storage structure including a first data storage material layer. The second vertical memory structure includes a second data storage structure including a second data storage material layer that is different from the first data storage material layer.

### CROSS-REFERENCE TO RELATED APPLICATION(S)

This application claims the benefit under 35 USC 119(a) of Korean Patent Application No. 10-2021-0193035, filed on Dec. 30, 2021, and No. 10-2022-0009407, filed on Jan. 21, 2022, in the Korean Intellectual Property Office, the entire disclosures of which are incorporated herein by reference for all purposes.

### BACKGROUND

Embodiments relate to a semiconductor device and/or a data storage system including the same.

In various systems requiring data storage, a semiconductor device capable of storing high-capacity data has been demanded. Accordingly, measures for increasing a data storage capacity of a semiconductor device have been considered. For example, as one method for increasing the data storage capacity of the semiconductor device, a semiconductor device including three-dimensionally arranged memory cells instead of two-dimensionally arranged memory cells has been considered.

### SUMMARY

Example embodiments provide a semiconductor device capable of having an improved degree of integration.

Example embodiments provide a data storage system including the semiconductor device.

Example embodiments provide a vehicle system including the data storage system.

According to an example embodiment, a semiconductor device may include a first non-volatile memory structure, the first non-volatile memory structure including a first stack structure and a first vertical memory structure, the first stack structure including first conductive lines stacked while being spaced apart from each other in a vertical direction and the first vertical memory structure penetrating through the first stack structure in the vertical direction; a second non-volatile memory structure, the second non-volatile memory structure including a second stack structure and a second vertical memory structure, the second stack structure including second conductive lines stacked while being spaced apart from each other in the vertical direction and the second vertical memory structure penetrating through the second stack structure in the vertical direction; and a peripheral circuit structure electrically connected to the first non-volatile memory structure and the second non-volatile memory structure through interconnection structures. The peripheral circuit structure, the first non-volatile memory structure, and the second non-volatile memory structure may overlap each other in the vertical direction. The first vertical memory structure may include a first data storage structure and the first data storage structure may include a first data storage material layer. The second vertical memory structure may include a second data storage structure and the second data storage structure may include a second data storage material layer. The second data storage material layer may be different from the first data storage material layer.

According to an example embodiment, a semiconductor device may include a package substrate, a semiconductor chip on the package substrate, and a molded layer covering at least side surfaces of the semiconductor chip on the package substrate. The semiconductor chip may include a first non-volatile memory structure and a second non-volatile memory structure. The first non-volatile memory structure may include a first stack structure and first vertical memory devices. The first stack structure may include first conductive lines stacked while being spaced apart from each other in a vertical direction and the first vertical memory structures may penetrate through the first conductive lines in the vertical direction. The second non-volatile memory structure may include a second stack structure and second vertical memory structures. The second stack structure may include second conductive lines stacked while being spaced apart from each other in the vertical direction and the second vertical memory structures may penetrate through the second conductive lines in the vertical direction. The first stack structure and the second stack structure may overlap each other in the vertical direction. The first vertical memory structure may include a first data storage structure. The second vertical memory structure may include a second data storage structure. The second data storage structure may be different from the first data storage structure.

According to an example embodiment, a data storage system may include a main board, a semiconductor device on the main board, and a controller electrically connected to the semiconductor device on the main board. The semiconductor device may include a first non-volatile memory structure, a second non-volatile memory structure, and a peripheral circuit structure electrically connected to the first non-volatile memory structure and the second non-volatile memory structure through interconnection structures. The first non-volatile memory structure may include a first stack structure and a first vertical memory structure penetrating through the first stack structure in a vertical direction. The first stack structure may include first conductive lines stacked while being spaced apart from each other in the vertical direction. The second non-volatile memory structure may include a second stack structure and a second vertical memory structure penetrating through the second stack structure in the vertical direction. The second stack structure may include second conductive lines stacked while being spaced apart from each other in the vertical direction. The peripheral circuit structure, the first non-volatile memory structure, and the second non-volatile memory structure may overlap each other in the vertical direction. The first vertical memory structure may include a first data storage structure. The first data storage structure may include a first data storage material layer. The second vertical memory structure may include a second data storage structure. The second data storage structure may include a second data storage material layer. The second data storage material layer may be different from the first data storage material layer.

### BRIEF DESCRIPTION OF DRAWINGS

The above and other aspects, features, and advantages of inventive concepts will be more clearly understood from the following detailed description, taken in conjunction with the accompanying drawings, in which:

FIG. 1 is a schematic perspective view of a semiconductor device according to an example embodiment;

FIG. 2 is a schematic diagram illustrating the semiconductor device according to an example embodiment;

FIG. 3A is a schematic diagram illustrating an example of the semiconductor device according to an example embodiment;

FIG. 3B is a schematic diagram illustrating a modified example of the semiconductor device according to an example embodiment;

FIG. 4A is a schematic diagram illustrating a modified example of the semiconductor device according to an example embodiment;

FIG. 4B is a schematic diagram illustrating a modified example of the semiconductor device according to an example embodiment;

FIG. 5A is a schematic perspective view illustrating an example of the semiconductor device according to an example embodiment;

FIG. 5B is a schematic perspective view illustrating a modified example of the semiconductor device according to an example embodiment;

FIGS. 6A and 6B are schematic cross-sectional views illustrating an example of the semiconductor device according to an example embodiment;

FIG. 7 is a schematic cross-sectional view illustrating a modified example of the semiconductor device according to an example embodiment;

FIGS. 8A and 8B are schematic partial enlarged views illustrating an example of the semiconductor device according to an example embodiment;

FIG. 9 is a schematic partial enlarged view illustrating a modified example of the semiconductor device according to an example embodiment;

FIGS. 10 to 12 are schematic diagrams illustrating modified examples of the semiconductor device according to an example embodiment;

FIGS. 13 and 14 are schematic diagrams illustrating modified examples of the semiconductor device according to an example embodiment;

FIGS. 15 and 16 are schematic diagrams illustrating modified examples of the semiconductor device according to an example embodiment;

FIG. 17A is a schematic cross-sectional view illustrating a modified example of the semiconductor device according to an example embodiment;

FIG. 17B is a schematic cross-sectional view illustrating a modified example of the semiconductor device according to an example embodiment;

FIG. 17C is a schematic cross-sectional view illustrating a modified example of the semiconductor device according to an example embodiment;

FIGS. 18 to 19B are schematic diagrams illustrating modified examples of the semiconductor device according to an example embodiment;

FIG. 20 is a schematic diagram illustrating a modified example of the semiconductor device according to an example embodiment;

FIG. 21 is a schematic diagram illustrating a modified example of the semiconductor device according to an example embodiment;

FIG. 22 is a schematic diagram illustrating a modified example of the semiconductor device according to an example embodiment;

FIGS. 23 and 24 are schematic diagrams illustrating a modified example of the semiconductor device according to an example embodiment;

FIG. 25 is a schematic cross-sectional view illustrating a modified example of the semiconductor device according to an example embodiment;

FIGS. 26 to 27B are schematic diagrams illustrating a modified example of the semiconductor device according to an example embodiment;

FIGS. 28 and 29 are schematic diagrams illustrating modified examples of the semiconductor device according to an example embodiment;

FIGS. 30 and 31 are schematic diagrams illustrating a modified example of the semiconductor device according to an example embodiment;

FIGS. 32 and 33 are schematic diagrams illustrating a modified example of the semiconductor device according to an example embodiment;

FIG. 34 is a schematic diagram illustrating a modified example of the semiconductor device according to an example embodiment;

FIG. 35 is a schematic diagram illustrating a modified example of the semiconductor device according to an example embodiment;

FIG. 36 is a schematic diagram illustrating a modified example of the semiconductor device according to an example embodiment;

FIG. 37 is a schematic diagram illustrating a system including the semiconductor device according to an example embodiment; and

FIG. 38 is a schematic perspective view of the system including the semiconductor device according to an example embodiment.

### DETAILED DESCRIPTION

Hereinafter, the terms such as ‘on’, ‘upper’, ‘upper surface’, ‘beneath’, ‘lower’, and ‘lower surface’ may be understood as being referred to based on drawings except for a case where they are denoted by reference numerals and are separately referred to. The terms such as “upper”, “middle”, and “lower” may be replaced with other terms such as “first”, “second”, and “third” and be used to describe components of the present specification. The terms such as “first”, “second”, and “third” may be used to describe various components, but these components are not limited by these terms, and a “first component” may also be referred to as a “second component”.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

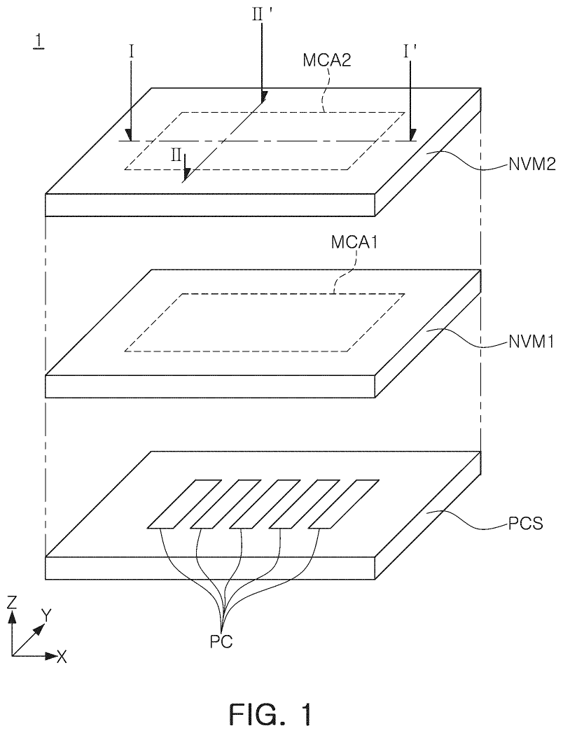

First, an illustrative example of a semiconductor device according to an example embodiment will be described with reference to FIG. 1. FIG. 1 is a schematic perspective view of a semiconductor device according to an example embodiment.

Referring to FIG. 1, a semiconductor device 1 according to an example embodiment may include a first non-volatile memory structure NVM1 having a first memory cell array region MCA1, a second non-volatile memory structure NVM2 having a second memory cell array region MCA2 vertically overlapping the first memory cell array region NVM1, and a peripheral circuit structure PCS electrically connected to the first non-volatile memory structure NVM1 and the second non-volatile memory structure NVM2 through interconnection structures. The peripheral circuit structure PCS may include a peripheral circuit PC for operating the first non-volatile memory structure NVM1 and the second non-volatile memory structure NVM2. The first non-volatile memory structure NVM1 and the second non-volatile memory structure NVM2 may be different non-volatile memories. The peripheral circuit structure PCS, the first non-volatile memory structure NVM1, and the second non-volatile memory structure NVM2 may be sequentially stacked in a vertical direction Z.

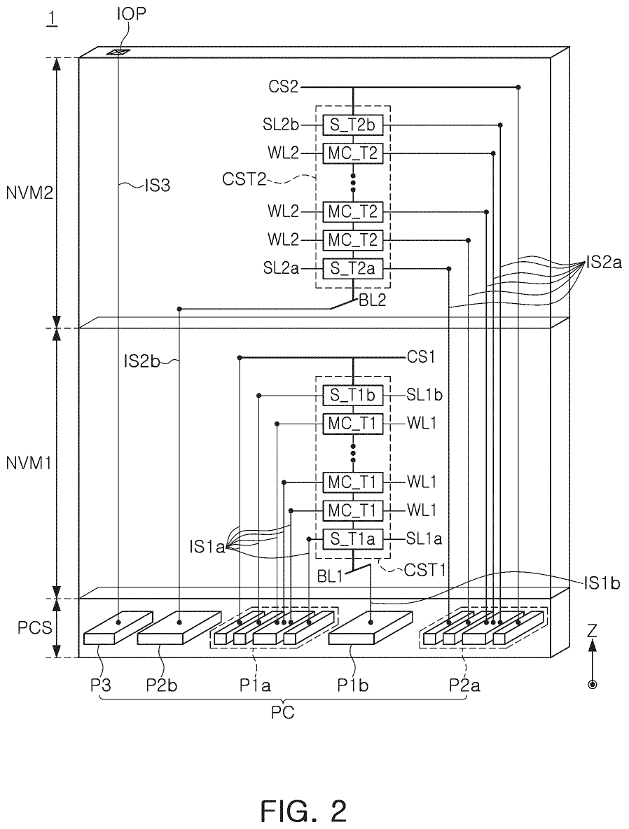

Next, an example of the semiconductor device 1 according to an example embodiment will be described with reference to FIG. 2. FIG. 2 is a schematic diagram illustrating the semiconductor device according to an example embodiment.

Referring to FIGS. 1 and 2, the first non-volatile memory structure NVM1 may include a first bit line BL1, a first lower select line SL1a, first word lines WL1, a first upper select line SL1b, a first common source CS1, and a first memory cell string CST1.

The first memory cell string CST1 may be disposed between the first bit line BL1 and the first common source CS1. The first bit line BL1 may be disposed below the first memory cell string CST1, and the first common source CS1 may be disposed above the first memory cell string CST1. A plurality of first memory cell strings CST1 may be disposed to constitute the first memory cell array region MCA1.

The first memory cell string CST1 may include a first lower select transistor S_T1a, first memory cell transistors MC_T1 sequentially arranged in the vertical direction Z on the first lower select transistor S_T1a, and a first upper select transistor S_T1b disposed on the first memory cell transistor MC_T1. The first memory cell transistors MC_T1 may be connected to each other in series in the vertical direction Z.

The first lower select line SL1a may be a gate electrode of the first lower select transistor S_T1a. The first word lines WL1 may be gate electrodes of the first memory cell transistors MC_T1. The first upper select line SL1b may be a gate electrode of the first upper select transistor S_T1b. Accordingly, the first lower select line SL1a, the first word lines WL1 and the first upper select line SL1b may be gate electrodes SL1a, WL1, and SL1b of the first memory cell string CST1.

The second non-volatile memory structure NVM2 may include a second bit line BL2, a second lower select line SL2a, second word lines WL2, a second upper select line SL2b, a second common source CS2, and a second memory cell string CST2.

The second memory cell string CST2 may be disposed between the second bit line BL2 and the second common source CS2. The second bit line BL2 may be disposed below the second memory cell string CST2, and the second common source CS2 may be disposed above the second memory cell string CST2. A plurality of second memory cell strings CST2 may be disposed to constitute the second memory cell array region MCA2.

The second memory cell string CST2 may include a second lower select transistor S_T2a, second memory cell transistors MC_T2 sequentially arranged in the vertical direction Z on the second lower select transistor S_T2a, and a second upper select transistor S_T2b disposed on the second memory cell transistor MC_T2.

The second lower select line SL2a may be a gate electrode of the second lower select transistor S_T2a. The second word lines WL2 may be gate electrodes of the second memory cell transistors MC_T2. The second upper select line SL2b may be a gate electrode of the second upper select transistor S_T2b. Accordingly, the second lower select line SL2a, the second word lines WL2, and the second upper select line SL2b may be gate electrodes SL2a, WL2, and SL2b of the second memory cell string CST2.

The peripheral circuit structure PCS may include a first decoder circuit P1a, a second decoder circuit P2a, a first peripheral circuit P1b, a second peripheral circuit P2b, and a logic circuit P3.

The semiconductor device 1 may further include interconnection structures IS1a, IS1b, IS2a, and IS2b electrically connecting the first non-volatile memory structure NVM1 and the second non-volatile memory structure NVM2 to the peripheral circuit structure PCS. For example, the interconnection structures IS1a, IS1b, IS2a, and IS2b may include an interconnection pattern IS1b electrically connecting the first bit line BL1 and the first peripheral circuit P1b, interconnection patterns IS1a electrically connecting the gate electrodes SL1a, WL1, and SL1b of the first memory cell string CST1 and the first common source CS1 to the first decoder circuit P1a, an interconnection pattern IS2b electrically connecting the second bit line BL2 and the second peripheral circuit P2b, and interconnection patterns IS2a electrically connecting the gate electrodes SL2a, WL2, and SL2b of the second memory cell string CST2 and the second common source CS2 to the second decoder circuit P2a. In example embodiments, the terms such as “interconnection pattern” may be referred to as “wiring” or “interconnection line”.

In an example embodiment, the first decoder circuit P1a and the first peripheral circuit P1b may execute a control operation for the first memory cell string CST1, the first bit line BL1, and the first common source CS1. Accordingly, information may be stored in first memory cells of the first memory cell transistors MC_T1 of the first memory cell string CST1 or information stored in the first memory cells may be read, through the first decoder circuit P1a and the first peripheral circuit P1b. For example, the first peripheral circuit P1b may be a circuit for sensing information (or data) in the first memory cells of the first memory cell transistors MC_T1 of the first memory cell string CST1 of the first non-volatile memory structure NVM1.

In an example embodiment, the second decoder circuit P2a and the second peripheral circuit P2b may execute a control operation for the second memory cell string CST2, the second bit line BL2, and the second common source CS2. Accordingly, information may be stored in second memory cells of the second memory cell transistors MC_T2 of the second memory cell string CST2 or information stored in the second memory cells may be read, through the second decoder circuit P2a and the second peripheral circuit P2b. For example, the second peripheral circuit P2b may be a circuit for sensing information (or data) in the second memory cells of the second memory cell transistors MC_T2 of the second memory cell string CST2 of the second non-volatile memory structure NVM2.

The first decoder circuit P1a and the first peripheral circuit P1b, and the second decoder circuit P2a and the second peripheral circuit P2b may be controlled by the logic circuit P3.

The semiconductor device 1 may further include an input/output pad IOP and an input/output interconnection pattern IS3 electrically connecting the input/output pad IOP and an input/output circuit of the logic circuit P3 to each other.

In an example embodiment, the first memory cells of the first memory cell transistors MC_T1 may be any one of a memory cell of a flash memory storing data by trapping charges, a memory cell of a resistive random access memory storing data using a change in resistance according to a change in oxygen vacancy concentration, a memory cell of a phase change random access memory storing data using a change in resistance according to a phase change, and a memory cell of a ferroelectric random access memory storing data using a ferroelectric, and the second memory cells of the second memory cell transistors MC_T2 may be different types of memory cells from the first memory cells of the first memory cell transistors MC_T1 among a memory cell of a flash memory storing data by trapping charges, a memory cell of a resistive random access memory storing data using a change in resistance according to a change in oxygen vacancy concentration, a memory cell of a phase change random access memory storing data using a change in resistance according to a phase change, and a memory cell of a ferroelectric random access memory storing data using a ferroelectric.

The types of the first memory cells of the first memory cell transistors MC_T1 and the types of the second memory cells of the second memory cell transistors MC_T2 are not limited to the above-described examples, and a case where the first memory cells of the first memory cell transistors MC_T1 and the second memory cells of the second memory cell transistors MC_T2 are various types of other non-volatile memory cells may also be included in an example embodiment.

In an example embodiment, the semiconductor device 1 includes different types of the first and second non-volatile memory structures NVM1 and NVM2 arranged in a vertical direction, and a degree of integration of the semiconductor device 1 may thus be improved.

In an example embodiment, the different types of the first and second non-volatile memory structures NVM1 and NVM2 may have different operating speeds. For example, a non-volatile memory having a relatively fast operating speed, of the first and second non-volatile memory structures NVM1 and NVM2 may include a resistive random access memory, a phase change random access memory, or a ferroelectric random access memory, and a non-volatile memory having a relatively slow operating speed, of the first and second non-volatile memory structures NVM1 and NVM2 may include a flash memory. Accordingly, the semiconductor device 1 that has optimized performance may be provided.

In an example embodiment, one of the different types of the first and second non-volatile memory structures NVM1 and NVM2 may be a stable non-volatile memory, and the other of the different types of the first and second non-volatile memory structures NVM1 and NVM2 may be a non-volatile memory having a fast operating speed. For example, a non-volatile memory having a relatively fast operating speed, of the first and second non-volatile memory structures NVM1 and NVM2 may include a resistive random access memory, a phase change random access memory, or a ferroelectric random access memory, and a relatively stabler non-volatile memory of the first and second non-volatile memory structures NVM1 and NVM2 may include a flash memory. Accordingly, the semiconductor device 1 that is stable and has optimized performance may be provided.

In an example embodiment, the different types of the first and second non-volatile memory structures NVM1 and NVM2 may be used for different purposes, and thus, the semiconductor device 1 that is stable and reliable while having an improved overall memory capacity may be provided. For example, a non-volatile memory structure in a situation in which information needs to be quickly read and written (e.g., a situation in which information required for autonomous driving of a vehicle needs to be stored and analyzed), of the first and second non-volatile memory structures NVM1 and NVM2 may include a resistive random access memory, a phase change random access memory, or a ferroelectric random access memory, and a non-volatile memory in a situation in which general large-capacity data (e.g., data of a vehicle black box) needs to be stored, of the first and second non-volatile memory structures NVM1 and NVM2 may include a flash memory.

In an example embodiment, in the semiconductor device 1, a program in which reading/writing is frequently repeated may be stored in a non-volatile memory having a fast operating speed, of the different non-volatile memory structures, and when general data is stored, the general data may be stored in a stabler non-volatile memory, of the different non-volatile memory structures. Accordingly, the semiconductor device 1 that is stable while having a fast data storage speed may be provided.

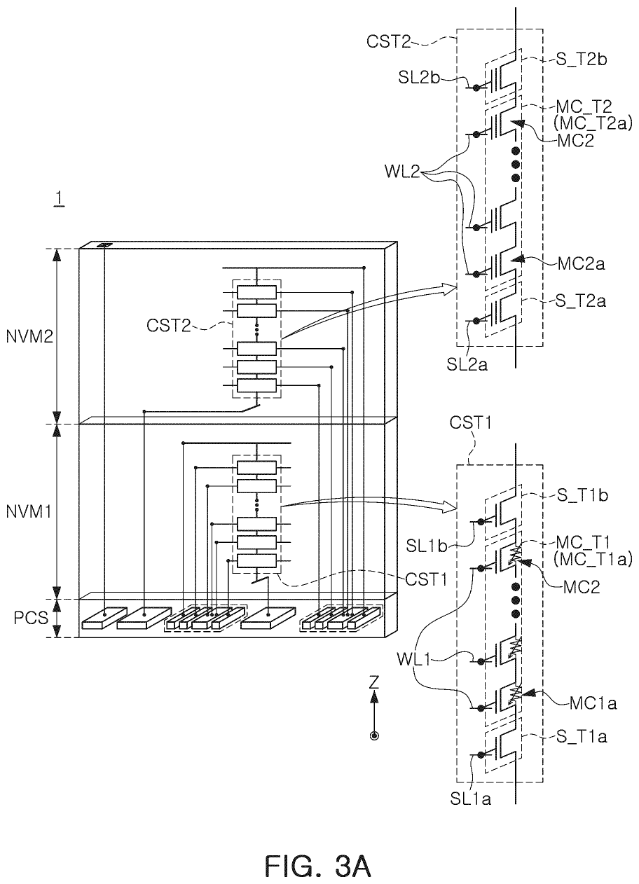

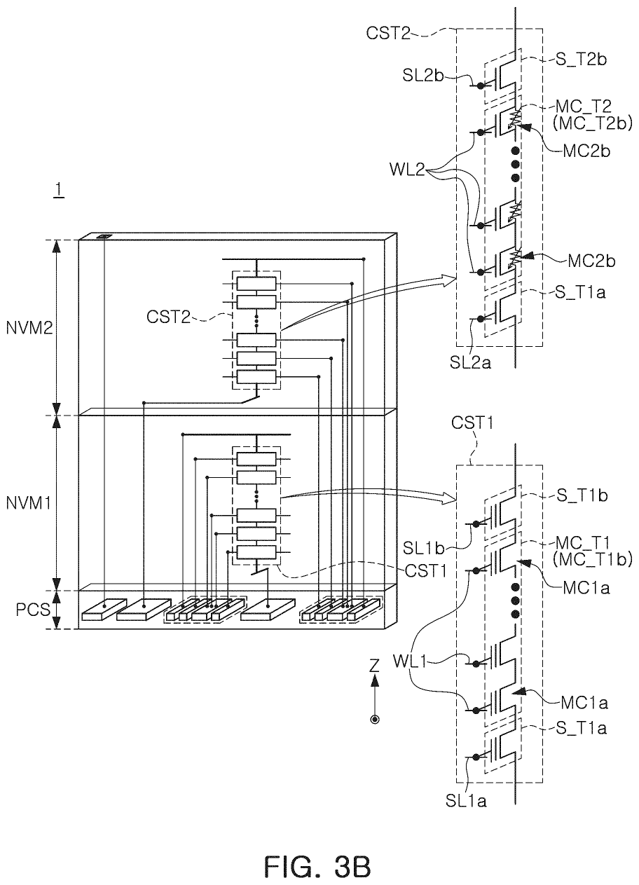

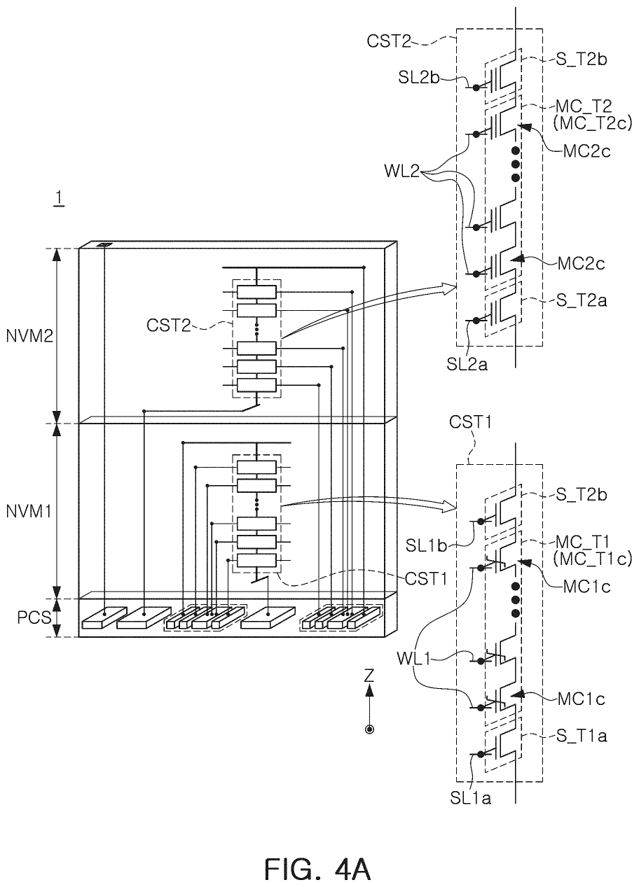

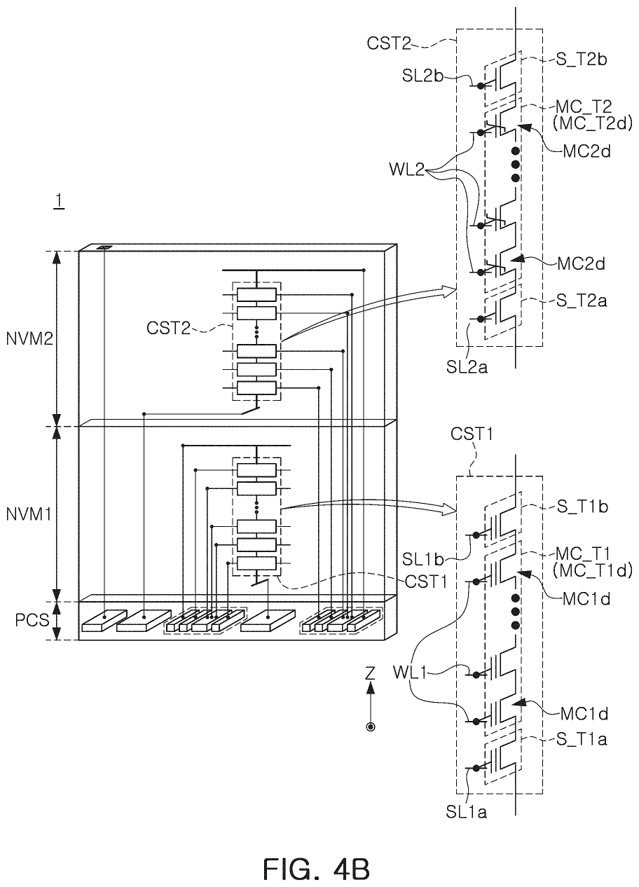

Next, various examples of a circuit of the first memory cell string CST1 and a circuit of the second memory cell string CST2 in FIG. 2 are described with reference to FIGS. 3A to 4B. FIGS. 3A to 4B are schematic diagrams illustrating a circuit of the first memory cell string CST1 and a circuit of the second memory cell string CST2 in FIG. 2.

In an example, referring to FIGS. 2 and 3A, in the first memory cell string CST1, the first memory cell transistors MC_T1 may be variable resistive memory cell transistors MC_T1a including first memory cells MC1a, and in the second memory cell string CST2, the second memory cell transistors MC_T2 may be flash memory cell transistors MC_T2a including second memory cells MC2a. The first memory cells MC1a may be sequentially arranged in the vertical direction Z, and the second memory cells MC2a may be sequentially arranged in the vertical direction Z.

The first memory cells MC1a may be memory cells of a resistive random access memory (ReRAM), and the second memory cells MC2a may be memory cells of a flash memory. For example, the first memory cells MC1a may be memory cells of a variable resistive random access memory storing data using a variable resistive material whose resistance varies depending on an oxygen vacancy concentration, and the second memory cells MC2a may be memory cells of a charge trap flash (CTF)-type flash memory storing data by trapping charges. In another example, the first memory cells MC1a may be memory cells of a phase change random access memory (PRAM) storing data using a resistance change according to a phase change.

In another example, referring to FIGS. 2 and 3B, in the first memory cell string CST1, the first memory cell transistors MC_T1 may be flash memory cell transistors MC_T1b including first memory cells MC1b, and in the second memory cell string CST2, the second memory cell transistors MC_T2 may be variable resistive memory cell transistors MC_T2b including second memory cells MC2b. For example, the first memory cells MC1b may be memory cells of a flash memory, and the second memory cells MC2b may be memory cells of a resistive random access memory (ReRAM). For example, the first memory cells MC1b may be memory cells of a CTF-type flash memory storing data by trapping charges, and the second memory cells MC2b may be memory cells of a variable resistive random access memory storing data using a variable resistive material whose resistance varies depending on an oxygen vacancy concentration. In another example, the second memory cells MC2b may be memory cells of a phase change random access memory (PRAM) storing data using a resistance change according to a phase change.

In another example, referring to FIGS. 2 and 4A, in the first memory cell string CST1, the first memory cell transistors MC_T1 may be ferroelectric memory cell transistors MC_T1c including first memory cells MC1c, and in the second memory cell string CST2, the second memory cell transistors MC_T2 may be a plurality of flash memory cell transistors MC_T2c including second memory cells MC2c. The first memory cells MC1c may be memory cells of a ferroelectric random access memory (FeRAM) storing data using a ferroelectric, and the second memory cells MC2c may be memory cells of a flash memory.

In another example, referring to FIGS. 2 and 4B, in the first memory cell string CST1, the first memory cell transistors MC_T1 may be a plurality of flash memory cell transistors MC_T1d including first memory cells MC1d, and in the second memory cell string CST2, the second memory cell transistors MC_T2 may be ferroelectric memory cell transistors MC_T2d including second memory cells MC2d. The first memory cells MC1d may be memory cells of a flash memory, and the second memory cells MC2d may be memory cells of a ferroelectric random access memory (FeRAM) storing data using a ferroelectric.

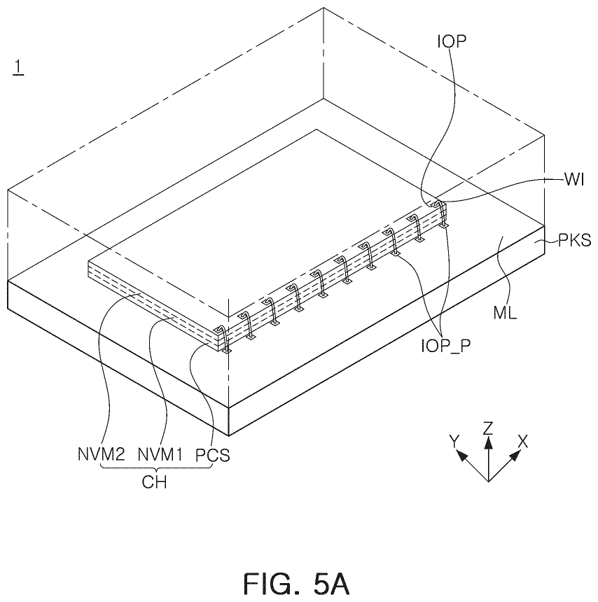

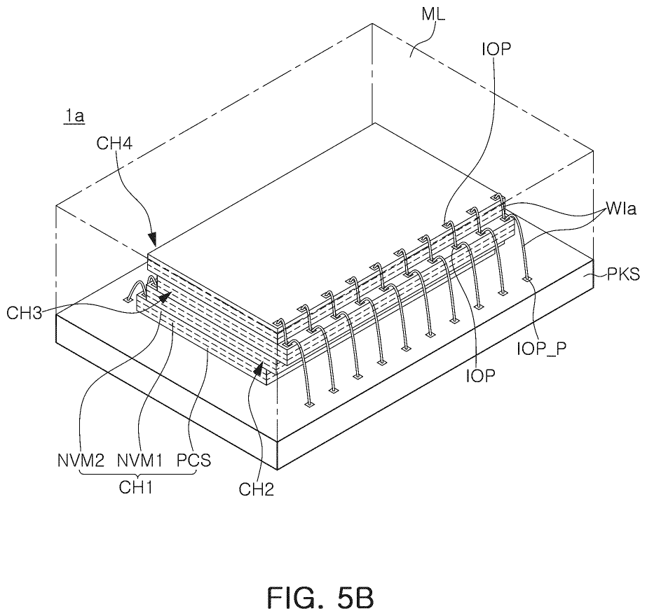

Next, an illustrative example of the semiconductor device 1 according to an example embodiment will be described with reference to FIG. 5A. FIG. 5A is a schematic perspective view illustrating an example of the semiconductor device according to an example embodiment.

Referring to FIGS. 1, 2A, and 5A, the semiconductor device 1 according to an example embodiment may further include a package substrate PKS and a molded layer ML disposed on the package substrate PKS.

The first non-volatile memory structure NVM1, the second non-volatile memory structure NVM2, and the peripheral circuit structure PCS described above may constitute one semiconductor chip CH.

In an example, the peripheral circuit structure PCS may constitute a peripheral circuit chip, the first non-volatile memory structure NVM1 may constitute a first memory chip bonded to the peripheral circuit chip, and the second non-volatile memory structure NVM2 may constitute a second memory chip bonded to the first memory chip. Accordingly, the semiconductor chip CH may be formed by bonding three stacked chips to each other.

In another example, the peripheral circuit structure PCS may constitute a peripheral circuit chip, and the first non-volatile memory structure NVM1 and the second non-volatile memory structure NVM2 may constitute a single memory chip bonded to the peripheral circuit chip. Accordingly, the semiconductor chip CH may be formed by bonding two stacked chips to each other.

In another example, the peripheral circuit structure PCS and the first non-volatile memory structure NVM1 may constitute a first chip, and the second non-volatile memory structure NVM2 may constitute a second chip bonded to the first chip. Accordingly, the semiconductor chip CH may be formed by bonding two stacked chips to each other.

In another example, the peripheral circuit structure PCS, the first non-volatile memory structure NVM1 and the second non-volatile memory structure NVM2 may constitute one semiconductor chip CH.

The semiconductor chip CH may be mounted on the package substrate PKS.

The semiconductor chip CH may include input/output pads IOP, and the package substrate PKS may include package input/output pads IOP_P.

The semiconductor device 1 may further include interconnection structures WI electrically connecting the input/output pads IOP of the semiconductor chip CH and the package input/output pads IOP_P of the package substrate PKS to each other.

In an example embodiment, the input/output pads IOP of the semiconductor chip CH and the package input/output pads IOP_P of the package substrate PKS may be electrically connected to each other by bonding wire-type connection structures WI, but an example embodiment is not limited thereto. For example, the input/output pads IOP of the semiconductor chip CH and the package input/output pads IOP_P of the package substrate PKS may be electrically connected to each other in a bump connection manner of a flip-chip structure or a direct bonding manner.

The molded layer ML may cover at least side surfaces of the semiconductor chip CH. The molded layer ML may include an insulating material such as an epoxy molding member used in a semiconductor package.

The molded layer ML may cover side surfaces and an upper surface of the semiconductor chip CH.

Next, a modified example of the semiconductor device 1 according to an example embodiment will be described with reference to FIG. 5B. FIG. 5B is a schematic perspective view illustrating a modified example of the semiconductor device according to an example embodiment.

Referring to FIGS. 1, 2A, and 5B, the semiconductor device 1 according to an example embodiment may further include a package substrate PKS, a plurality of semiconductor chips CH1, CH2, CH3, and CH4 stacked on the package substrate PKS, and a molded layer ML covering the semiconductor chips CH1, CH2, CH3, and CH4 on the package substrate PKS.

Each of the semiconductor chips CH1, CH2, CH3, and CH4 may include the first non-volatile memory structure NVM1, the second non-volatile memory structure NVM2, and the peripheral circuit structure PCS described above.

In an example, the peripheral circuit structure PCS may constitute a peripheral circuit chip, the first non-volatile memory structure NVM1 may constitute a first memory chip bonded to the peripheral circuit chip, and the second non-volatile memory structure NVM2 may constitute a second memory chip bonded to the first memory chip. Accordingly, the semiconductor chip CH may be formed by bonding three chips PCS, NVM1, and NVM2 to each other.

Each of the semiconductor chips CH1, CH2, CH3, and CH4 may include input/output pads IOP, and the package substrate PKS may include package input/output pads IOP P.

The semiconductor device 1 may further include interconnection structures WIa electrically connecting the input/output pads IOP of each of the semiconductor chips CH1, CH2, CH3, and CH4 and the package input/output pads IOP_P of the package substrate PKS to each other.

In example embodiments, each of the semiconductor chips CH1, CH2, CH3, and CH4 may be substantially the same as the semiconductor chip CH (see FIG. 5A) that may include one chip, two stacked chips, or three stacked chips, as described with reference to FIG. 5A.

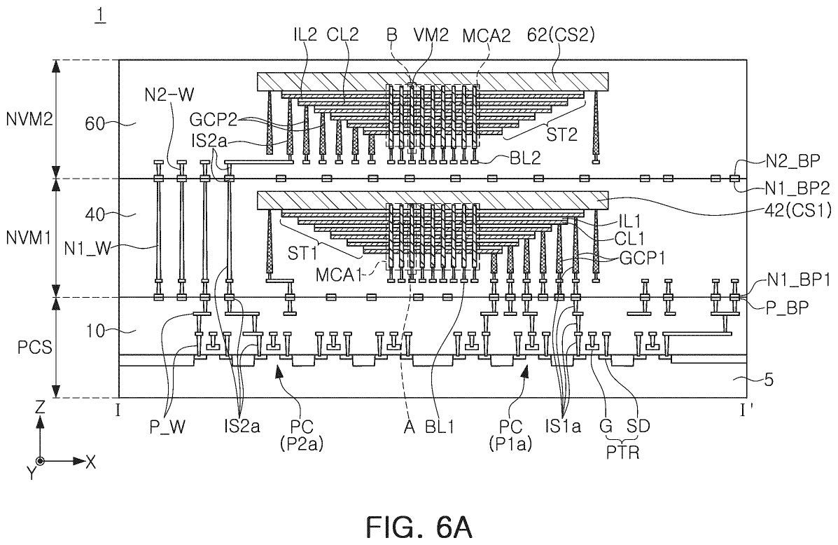

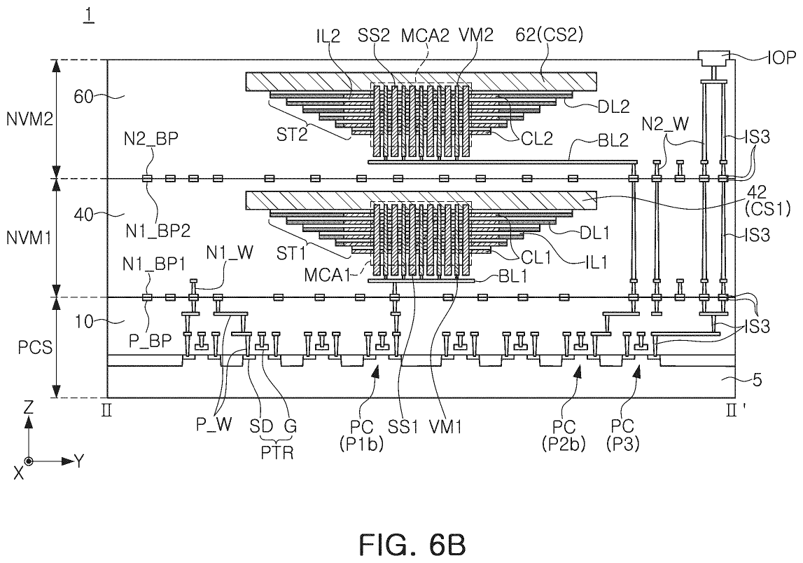

Next, an illustrative example of a cross-sectional structure of the semiconductor device 1 described with reference to FIGS. 1 and 2 will be described with reference to FIGS. 6A and 6B. FIG. 6A is a schematic cross-sectional view illustrating a region taken along line I-I′ of FIG. 1, and FIG. 6B is a schematic cross-sectional view illustrating a region taken along line II-II′ of FIG. 1.

Referring to FIGS. 1, 2, 6A and 6B, the peripheral circuit structure PCS described in FIGS. 1 and 2 may include a semiconductor substrate 5, the peripheral circuit PC disposed on the semiconductor substrate 5, a first insulating structure 10 covering the peripheral circuit PC on the semiconductor substrate 5, and first bonding pads P_BP embedded in an upper surface of the first insulating structure 10. The semiconductor substrate 5 may be formed of a semiconductor material such as silicon. The peripheral circuit PC may include transistors PTR each including a source/drain SD and a gate G.

The first non-volatile memory structure NVM1 described with reference to FIGS. 1 and 2 may include a first stack structure ST1, a first plate pattern 42 disposed on the first stack structure ST1, first vertical memory structures VM1 penetrating through the first stack structure ST1 and electrically connected to the first plate pattern 42, first bit lines BL1 electrically connected to the first vertical memory structures VM1 below the first stack structure ST1, a second insulating structure 40, second bonding pads N1_BP1 embedded in a lower surface of the second insulating structure 40, and third bonding pads N1_BP2 embedded in an upper surface of the second insulating structure 40.

The plate pattern 42 may include the first common source CS1.

A structure including the first stack structure ST1, the first plate pattern 42, the first vertical memory structures VM1, and the first bit lines BL1 may be embedded in the second insulating structure 40.

A plurality of first vertical memory structures VM1 may be disposed, and a region in which the plurality of first vertical memory structures VM1 are disposed may be defined as the first memory cell array region MCA1 (see FIG. 1).

The first stack structure ST1 may include first interlayer insulating layers IL1 and first conductive lines CL1 that are alternately and repeatedly stacked. The first conductive lines CL1 may be stacked while being spaced apart from each other in the vertical direction Z, and the first vertical memory structure VM1 may penetrate through the first conductive lines CL1.

The first conductive lines CL1 stacked while being spaced apart from each other in the vertical direction Z may constitute the gate electrodes SL1a, WL1, and SL1b of the first memory cell string CST1 described with reference to FIG. 2.

The first stack structure ST1 may have a stair shape around the first memory cell array region MCA1 (see FIG. 1) in which the first vertical memory structures VM1 are disposed. For example, in the first stack structure ST1, the first conductive lines CL1 that may constitute the gate electrodes SL1a, WL1, and SL1b may be arranged in a stair shape on a first side, for example, in a first direction X, of the first memory cell array region MCA1 (see FIG. 1) in which the first vertical memory structures VM1 are disposed, and gate contact plugs GCP1 may be disposed below the first conductive lines CL1 arranged in the stair shape.

The first stack structure ST1 may further include dummy lines DL1 disposed on substantially the same level as the first conductive lines CL1 on a second side, for example, in a second direction Y, of the first memory cell array region MCA1 (see FIG. 1) in which the first vertical memory structures VM1 are disposed, and the dummy lines DL1 may be arranged in a stair shape.

The first stack structure ST1 may have a shape in which a width thereof increases from the bottom toward the top.

The second non-volatile memory structure NVM2 described with reference to FIGS. 1 and 2 may include a second stack structure ST2, a second plate pattern 62 disposed on the second stack structure ST2, second vertical memory structures VM2 penetrating through the second stack structure ST2 and electrically connected to the second plate pattern 62, second bit lines BL2 electrically connected to the second vertical memory structures VM2 below the second stack structure ST2, a third insulating structure 60, and fourth bonding pads N2_BP embedded in a lower surface of the third insulating structure 60.

A structure including the second stack structure ST2, the second plate pattern 62, the second vertical memory structures VM2, and the second bit lines BL2 may be embedded in the third insulating structure 60.

The second plate pattern 62 may include the second common source CS2.

A plurality of second vertical memory structures VM2 may be disposed, and a region in which the plurality of second vertical memory structures VM2 are disposed may be defined as the second memory cell array region MCA2 (see FIG. 1).

The second stack structure ST2 may include second interlayer insulating layers IL2 and second conductive lines CL2 that are alternately and repeatedly stacked. The second conductive lines CL2 may be stacked while being spaced apart from each other in the vertical direction Z, and the second vertical memory structure VM2 may penetrate through the second conductive lines CL2.

The second conductive lines CL2 stacked while being spaced apart from each other in the vertical direction Z may constitute the gate electrodes SL2a, WL2, and SL2b of the second memory cell string CST2 described with reference to FIG. 2.

The second stack structure ST2 may have a stair shape around the second memory cell array region MCA2 (see FIG. 1) in which the second vertical memory structures VM2 are disposed. For example, in the second stack structure ST2, the second conductive lines CL2 that may constitute the gate electrodes SL2a, WL2, and SLb2 may be arranged in a stair shape on a first side, for example, in a first direction X, of the second memory cell array region MCA2 (see FIG. 1) in which the second vertical memory structures VM2 are disposed, and gate contact plugs GCP2 may be disposed below the second conductive lines CL2 arranged in the stair shape.

The second stack structure ST2 may further include dummy lines DL2 disposed on substantially the same level as the second conductive lines CL2 on a second side, for example, in a second direction Y, of the second memory cell array region MCA2 (see FIG. 2) in which the second vertical memory structures VM2 are disposed, and the dummy lines DL2 may be arranged in a stair shape.

The second stack structure ST2 may have a shape in which a width thereof increases from the bottom toward the top.

The first bonding pads P_BP and the second bonding pads N1_BP1 may be bonded to each other while being in contact with each other through intermetallic bonding. The third bonding pads N1_BP2 and the fourth bonding pads N2_BP may be bonded to each other while being in contact with each other through intermetallic bonding. For example, each of the first to fourth bonding pads P_BP, N1_BP1, N1_BP2, and N2_BP may include a metal material such as copper (Cu), the first bonding pads P_BP and the second bonding pads N1_BP1 may be bonded to each other while being in contact with each other by Cu—Cu bonding, and the third bonding pads N1_BP2 and the fourth bonding pads N2_BP may be bonded to each other while being in contact with each other by Cu—Cu bonding.

In example embodiments, the “intermetallic bonding” may refer to bonding of bonding pads formed of the same metal to each other through a thermal pressure bonding process.

The interconnection structures IS1a, IS1b, IS2a, and IS2b described with reference to FIGS. 1 and 2 may include interconnection patterns P_W of the peripheral circuit structure PCS, interconnection patterns N1_W of the first non-volatile memory structure NVM1, interconnection patterns N2_W of the second non-volatile memory structure NVM2, and the first to fourth bonding pads P_BP, N1_BP1, N1_BP2, and N2_BP.

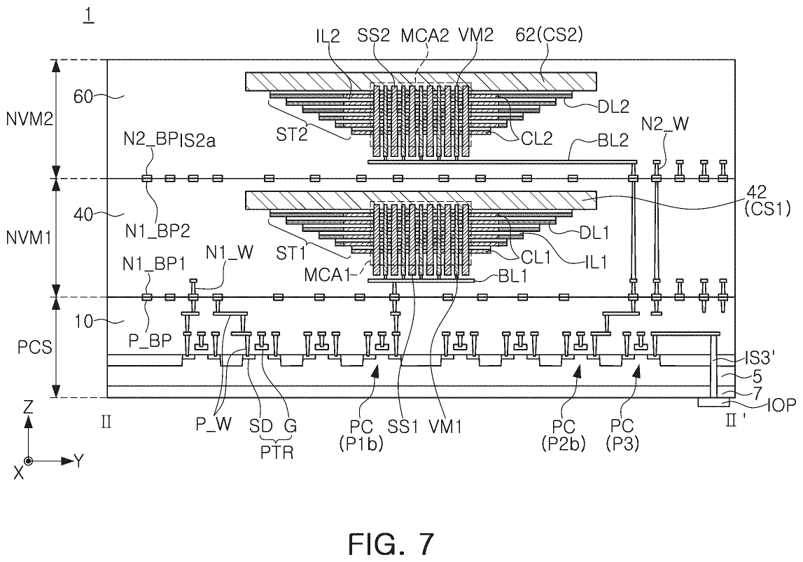

The input/output pad IOP may be disposed on the second non-volatile memory structure NVM2, but example embodiments are not limited thereto. A modified example in which the input/output pad IOP is disposed below the peripheral circuit structure PCS will be described with reference to FIG. 7. FIG. 7 is a schematic cross-sectional view illustrating a modified example of the semiconductor device according to an example embodiment, and illustrates a cross-sectional structure corresponding to FIG. 6B.

In a modified example, referring to FIG. 7, the peripheral circuit structure PCS described with reference to FIG. 6B may further include a buffer insulating layer 7 disposed below the semiconductor substrate 5, the input/output pad IOP may be modified to be disposed below the peripheral circuit structure PCS, and the input/output interconnection pattern IS3 (see FIG. 6B) may be modified into an interconnection pattern IS3′ penetrating through the semiconductor substrate 5 and the buffer insulating layer 7 and electrically connected to the peripheral circuit PC of the semiconductor substrate 5.

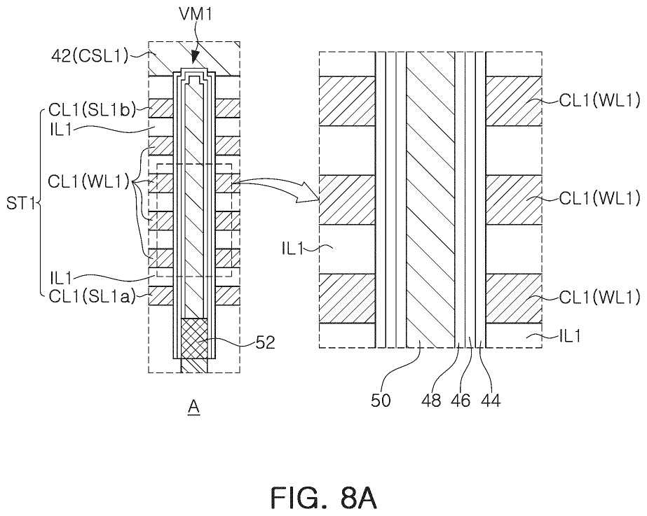

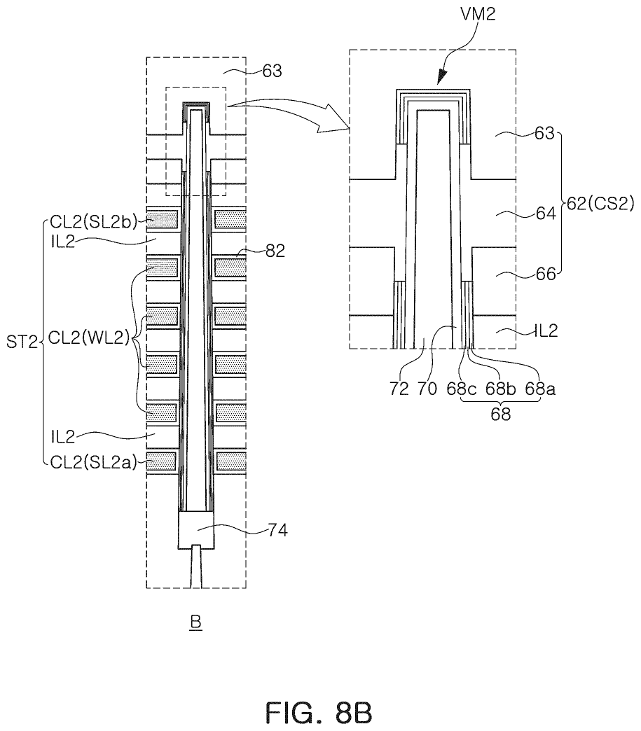

The first vertical memory structure VM1 described above may include a data storage structure of a variable resistive random access memory, and the second vertical memory structure VM2 may include a data storage structure of a flash memory. An example of the first vertical memory structure VM1 and an example of the second vertical memory structure VM2 will hereinafter be described with reference to FIGS. 8A and 8B, respectively.

An example of the first vertical memory structure VM1 described above will be described with reference to FIG. 8A. FIG. 8A is a partially enlarged view of the part denoted by ‘A’ of FIG. 6A.

Referring to FIGS. 6A and 8A, the first vertical memory structure VM1 may include an insulating core region 50, a data storage structure 48 surrounding side surfaces of the insulating core region 50, a channel layer 46 surrounding outer side surfaces of the data storage structure 48, a gate dielectric layer 44 surrounding outer side surfaces of the channel layer 46, and a pad pattern 52 in contact with the channel layer 46 below the insulating core region 50.

The channel layer 46 may include a semiconductor layer such as a silicon layer.

The pad pattern 52 may include a silicon layer having a conductivity-type of an N-type.

The gate dielectric layer 44 may include silicon oxide and/or a high dielectric.

In an example, the data storage structure 48 may include a variable resistive material layer. For example, the data storage structure 48 may include a variable resistive material whose resistance varies depending on an oxygen vacancy concentration. In an example, the data storage material of the data storage structure 48 may include a first element and oxygen. For example, the first element may be a metal element such as Al, Mg, Zr, Ti, La or Hf. For example, the data storage material of the data storage structure 48 may include a transition metal element in which a concentration of oxygen vacancies may vary in transition metal oxide such as hafnium oxide (HfO) and oxygen.

The data storage material of the data storage structure 48 may be any one of SiOx, AlOx, MgOx, ZrOx, HfOx, TiOx, LaOx, TaOx, WOx, and SiNx whose resistance may vary.

In another example, the data storage structure 48 may include a phase change material. For example, the data storage structure 48 may include a phase change material such as a chalcogenide-based material including Ge, Sb, and/or Te. Alternatively, the data storage structure 48 may include a phase change memory material including at least one element of Te or Se and at least one element of Ge, Sb, Bi, Pb, Sn, As, S, Si, P, O, N or In.

Accordingly, the second non-volatile memory structure NVM2 may include a data storage structure of a resistive random access memory (ReRAM) or a data storage structure of a phase change random access memory (PRAM).

Next, an example of the second vertical memory structure VM2 described above will be described with reference to FIG. 8B. FIG. 8B is a partially enlarged view of the part denoted by ‘B’ of FIG. 6A.

Referring to FIGS. 6A and 8B, the second vertical memory structure VM2 may include an insulating core region 72, a channel layer 70 covering at least side surfaces of the insulating core region 72, a data storage structure 68 covering at least outer side surfaces of the channel layer 70, and a pad pattern 74 in contact with the channel layer 70 below the insulating core region 72.

The data storage structure 68 of the second vertical memory structure VM2 may include a first dielectric layer 68c in contact with the channel layer 70, a data storage layer 68b in contact with the first dielectric layer 68c, and a second dielectric layer 68a in contact with the data storage layer 68b. The data storage layer 68b may be disposed between the first dielectric layer 68b and the second dielectric layer 68a.

The first dielectric layer 68c may include silicon oxide or silicon oxide doped with impurities. The second dielectric layer 68a may include at least one of silicon oxide and a high dielectric. The data storage layer 68b of the second vertical memory structure VM2 may include a material capable of trapping charges, such as silicon nitride. The data storage layer 68b of the second vertical memory structure VM2 may include regions capable of storing data in a semiconductor device such as a flash memory element. The channel layer 70 may include a silicon layer. The pad pattern 74 may include at least one of doped polysilicon, metal nitride (e.g., TiN, etc.), a metal (e.g., W, etc.), and a metal-semiconductor compound (e.g., TiSi, etc.).

The second stack structure ST2 may further include dielectric layers 82 covering a lower surface and an upper surface of each of the second conductive lines CL2 and extending between the second conductive lines CL2 and the second vertical memory structure VM2. The dielectric layer 82 may include at least one of silicon oxide or a high dielectric.

The second plate pattern 62 may include a first pattern layer 63, a second pattern layer 64 disposed below the first pattern layer 63, and a third pattern layer 66 disposed below the second pattern layer 64. At least one of the first pattern layer 63, the second pattern layer 64, and the third pattern layer 66 may include a polysilicon layer, for example, a polysilicon layer having a conductivity-type of an N-type. The second vertical memory structure VM2 may penetrate through the second and third pattern layers 64 and 66 and may be in contact with the first pattern layer 63. The second pattern layer 64 may penetrate through the data storage structure 68 and may be in contact with the channel layer 70.

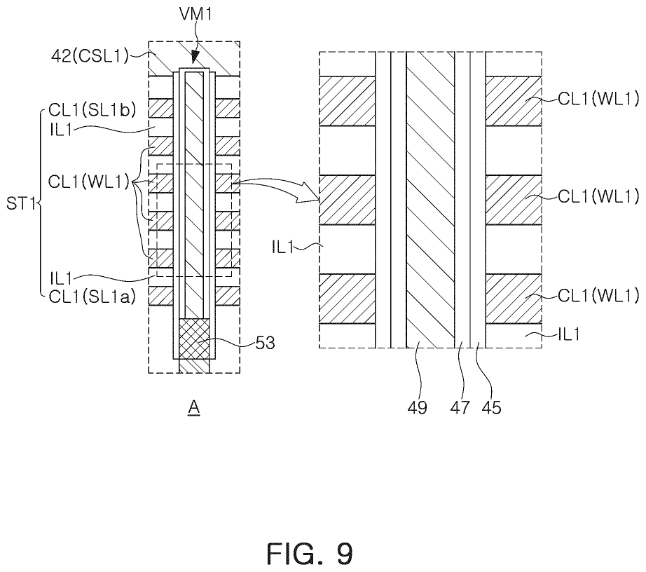

The first vertical memory structure VM1 described above may include a data storage structure of a variable resistive random access memory, but an example embodiment is not limited thereto. For example, the first vertical memory structure VM1 may include a data storage structure of a ferroelectric random access memory including a ferroelectric layer. An example in which the first vertical memory structure VM1 includes a data storage structure of a ferroelectric random access memory including a ferroelectric layer will be described with reference to FIG. 9.

Referring to FIG. 9, the first vertical memory structure VM1 may include an insulating core region 49, a channel layer 47 surrounding side surfaces of the insulating core region 49, a data storage structure 45 covering outer side surfaces of the channel layer 47, and a pad pattern 53 in contact with the channel layer 47 below the insulating core region 49.

The channel layer 47 may include a semiconductor layer such as a silicon layer.

The pad pattern 53 may include a silicon layer having a conductivity-type of an N-type.

The data storage structure 45 may include a ferroelectric layer. The ferroelectric layer of the data storage structure 45 may include a ferroelectric material such as PZT (Pb(Zr, Ti)O₃), but is not limited thereto. For example, the ferroelectric layer of the data storage structure 45 may include an HfO-based ferroelectric material, a ZrO-based ferroelectric material or the like. A material included in the data storage structure 45 is not limited to the above-described material. For example, the data storage structure 45 may include a ferroelectric material having magnetism maintaining electrical polarization even though an electric field is not applied from an external source, for example, HfO having ferroelectricity.

Accordingly, the second non-volatile memory structure NVM2 may store information by using a ferroelectric field effect transistor as a memory cell transistor.

Various modified examples of components of the semiconductor device will hereinafter be described. In various modified examples of the components of the semiconductor device to be described below, modified components or replaced components will be mainly described. In addition, components that may be modified or replaced to be described below will be described with reference to respective drawings, but components that may be modified may be combined with each other or be combined with the components of the example embodiment described above to constitute various example embodiments.

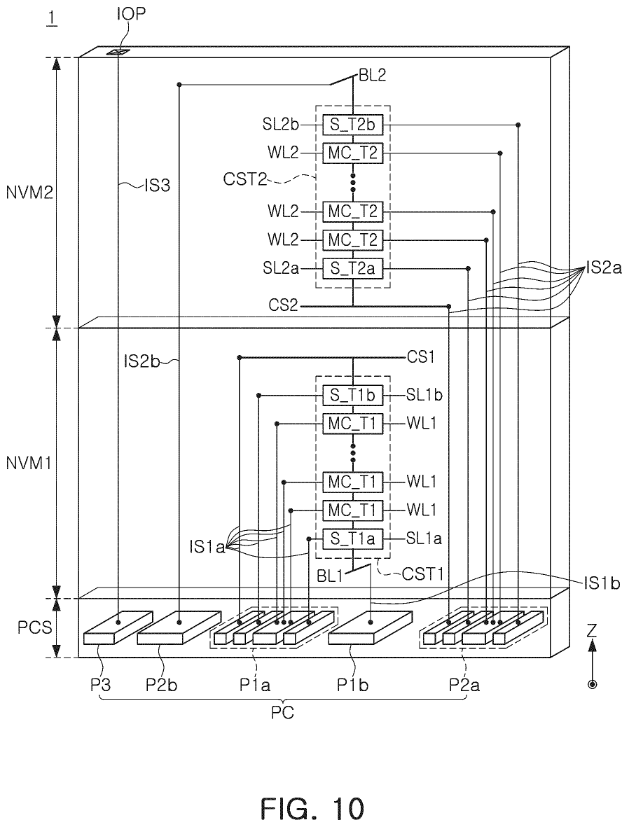

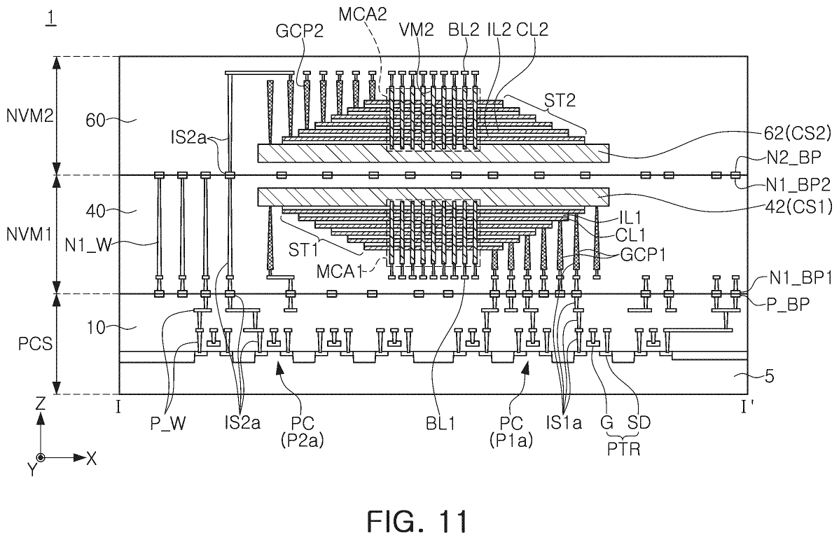

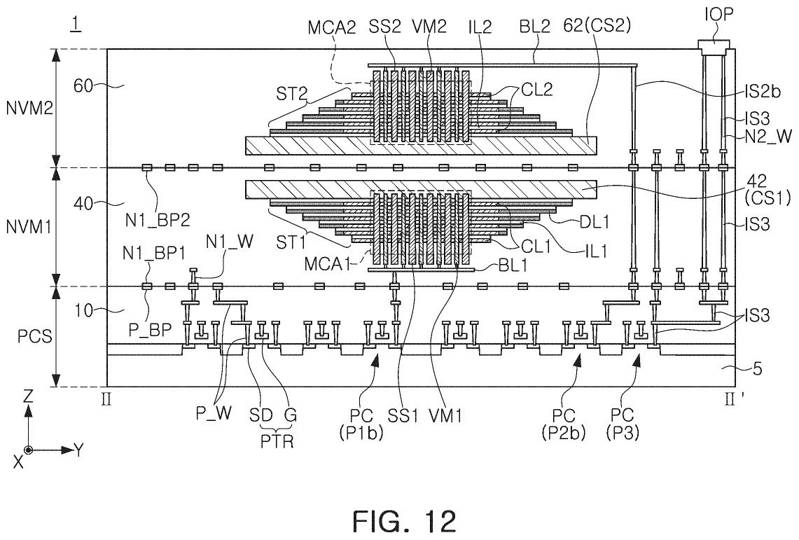

Modified examples of the semiconductor device according to an example embodiment will be described with reference to FIGS. 10 to 12. FIGS. 10 to 12 are schematic diagrams illustrating modified examples of the semiconductor device according to an example embodiment, wherein FIG. 10 illustrates a modified example of the semiconductor device illustrated in FIG. 2, FIG. 11 illustrates a modified example of the semiconductor device illustrated in FIG. 6A, and FIG. 12 illustrates a modified example of the semiconductor device illustrated in FIG. 6B.

Referring to FIGS. 10 to 12, the second common source CS2 in FIG. 2 may be modified to be disposed below the second lower select transistor ST_2a, and the second bit line BL2 in FIG. 2 may be modified to be disposed above the second upper select transistor ST_2b. The second plate pattern 62 described with reference to FIGS. 6A and 6B may be modified to be disposed below the second stack structure ST2, the second bit line BL2 may be modified to be disposed above the second stack structure ST2, and the second stack structure ST2 may be modified so that a width thereof decreases from the bottom toward the top. Accordingly, the second bit line BL2, the second stack structure ST2, and the second plate pattern 62 described with reference to FIGS. 6A and 6B may be modified to be turned upside down. For example, the second stack structure ST2 in FIGS. 6A and 6B may have a shape in which a width thereof increases from the bottom toward the top, while the second stack structure ST2 in FIGS. 11 and 12 may have a shape in which a width thereof decreases from the bottom toward the top.

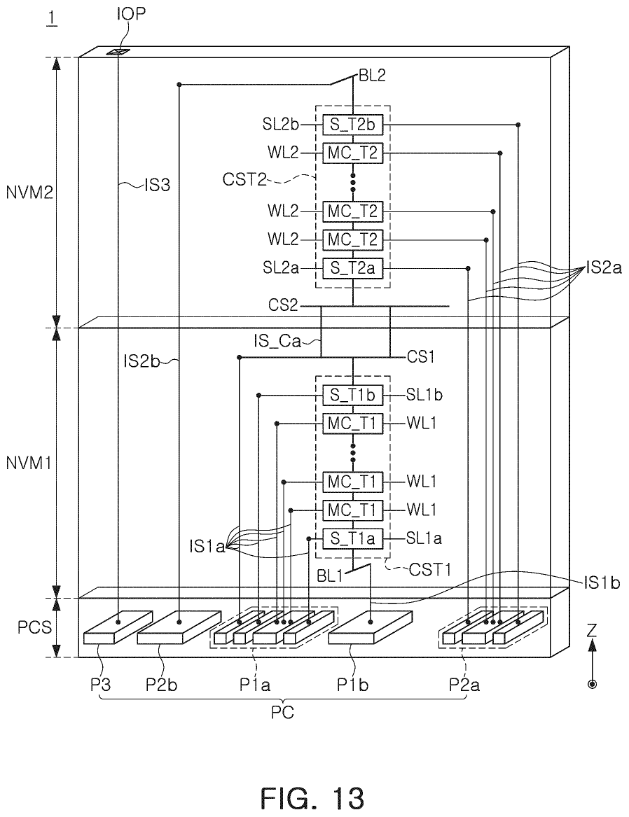

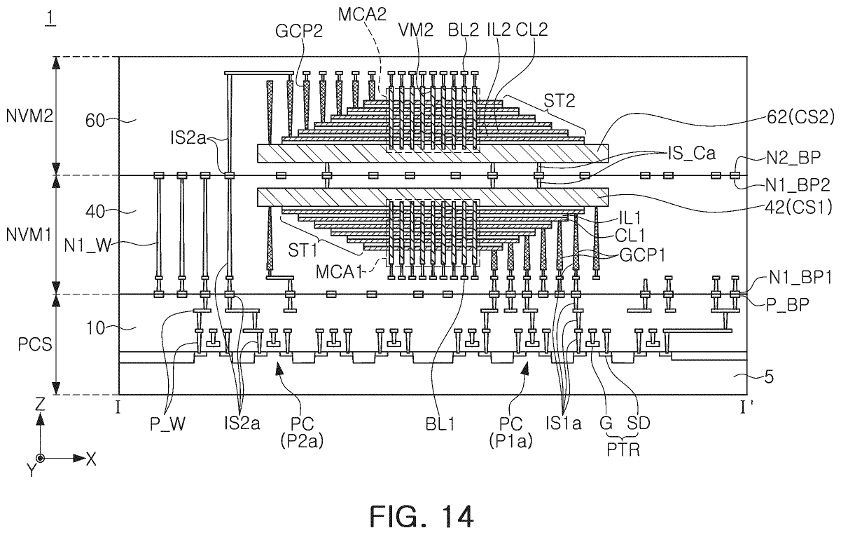

Modified examples of the semiconductor device according to an example embodiment will be described with reference to FIGS. 13 and 14. FIGS. 13 and 14 are schematic diagrams illustrating a modified example of the semiconductor device according to an example embodiment, wherein FIG. 13 illustrates a modified example of the semiconductor device illustrated in FIG. 10, and FIG. 14 illustrates a modified example of the semiconductor device illustrated in FIG. 11.

Referring to FIGS. 13 and 14, the semiconductor device 1 according to an example embodiment may further include a common source interconnection pattern IS_Ca electrically connecting the first common source CS1 and the second common source CS2 in FIGS. 10 to 12 to each other. The common source interconnection pattern IS_Ca may electrically connect the first plate pattern 42 and the second plate pattern 62 to each other between the first plate pattern 42 that may include the first common source CS1 and the second plate pattern 62 that may include the second common source CS2.

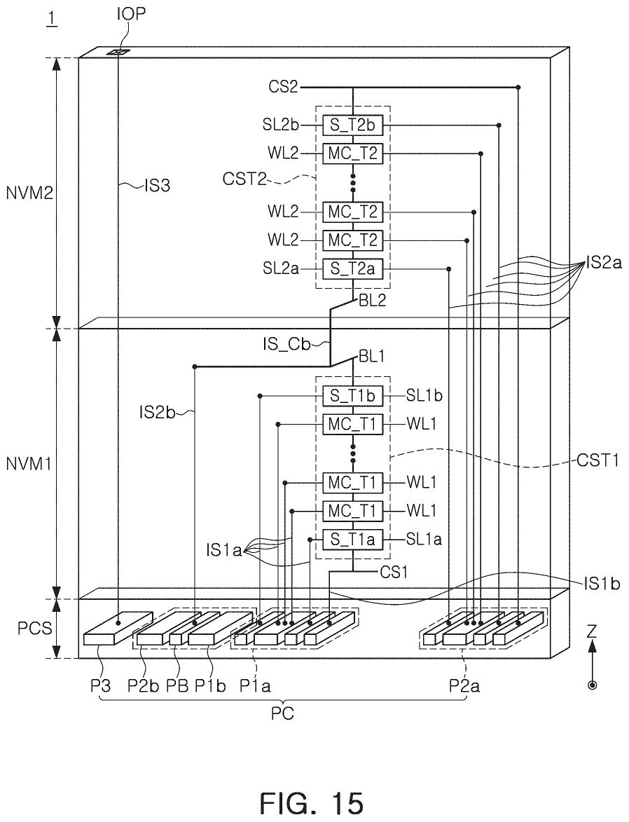

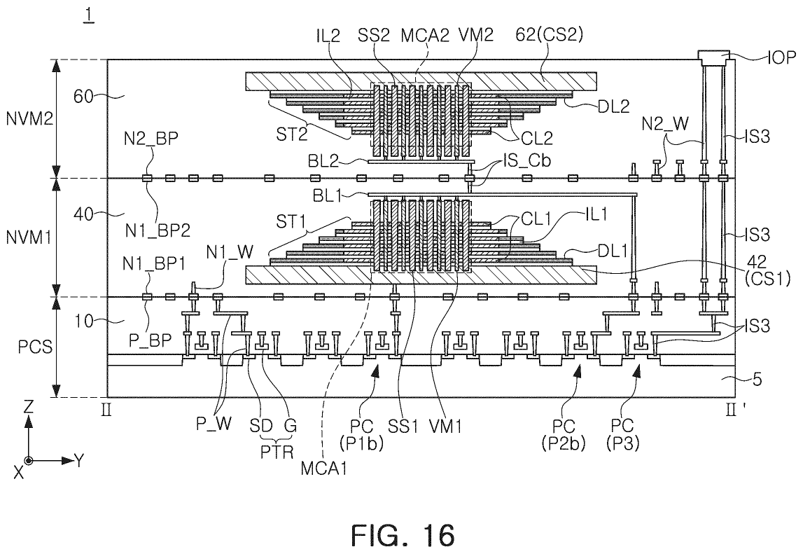

Modified examples of the semiconductor device according to an example embodiment will be described with reference to FIGS. 15 and 16. FIGS. 15 and 16 are schematic diagrams illustrating a modified example of the semiconductor device according to an example embodiment, wherein FIG. 15 illustrates a modified example of the semiconductor device illustrated in FIG. 2, and FIG. 16 illustrates a modified example of the semiconductor device illustrated in FIG. 6B.

Referring to FIGS. 15 and 16, the first common source CS1 in FIG. 2 may be modified to be disposed below the first lower select transistor ST_1a, and the first bit line BL1 in FIG. 2 may be modified to be disposed above the first upper select transistor ST_1b. The first plate pattern 42 described with reference to FIGS. 6A and 6B may be modified to be disposed below the first stack structure ST1, the first bit line BL1 may be modified to be disposed on the first stack structure ST1, and the first stack structure ST1 may be modified so that a width thereof decreases from the bottom toward the top. Accordingly, the first bit line BL1, the first stack structure ST1, and the first plate pattern 42 described with reference to FIGS. 6A and 6B may be modified to be turned upside down.

The semiconductor device 1 according to an example embodiment may further include a common bit line interconnection pattern IS_Cb electrically connecting the first bit line BL1 and the second bit line BL2 to each other. The common bit line interconnection pattern IS_Cb may electrically connect the first bit line BL1 and the second bit line BL2 to each other between the first bit line BL1 and the second bit line BL2. The input/output pad IOP may be disposed on the second non-volatile memory structure NVM2.

The semiconductor device 1 according to an example embodiment may further include a bit line connection structure IS2b electrically connecting the first bit line BL1 and the second bit line BL2 electrically connected to each other by the common bit line interconnection pattern IS_Cb to the peripheral circuit PC.

The peripheral circuit PC may include the first peripheral circuit P1b for sensing information (or data) in the first memory cells of the first memory cell transistors MC_T1 of the first memory cell string CST1 of the first non-volatile memory structure NVM1 and the second peripheral circuit P2b for sensing information (or data) in the second memory cells of the second memory cell transistors MC_T2 of the second memory cell string CST2 of the second non-volatile memory structure NVM2, as described with reference to FIG. 2.

The peripheral circuit PC may further include a distribution circuit PB electrically connected to the bit line connection structure IS2b. The distribution circuit PB may serve to electrically connect the first peripheral circuit P1b and the bit line connection structure IS2b to each other and electrically disconnect the second peripheral circuit P2b and the bit line connection structure IS2b from each other or electrically connect the second peripheral circuit P2b and the bit line connection structure IS2b to each other and electrically disconnect the first peripheral circuit P1b and the bit line connection structure IS2b, according to whether to sense the information (or the data) in the first memory cells of the first memory cell transistors MC_T1 of the first memory cell string CST1 of the first non-volatile memory structure NVM1 or sense the information (or the data) in the second memory cells of the second memory cell transistors MC_T2 of the second memory cell string CST2 of the second non-volatile memory structure NVM2.

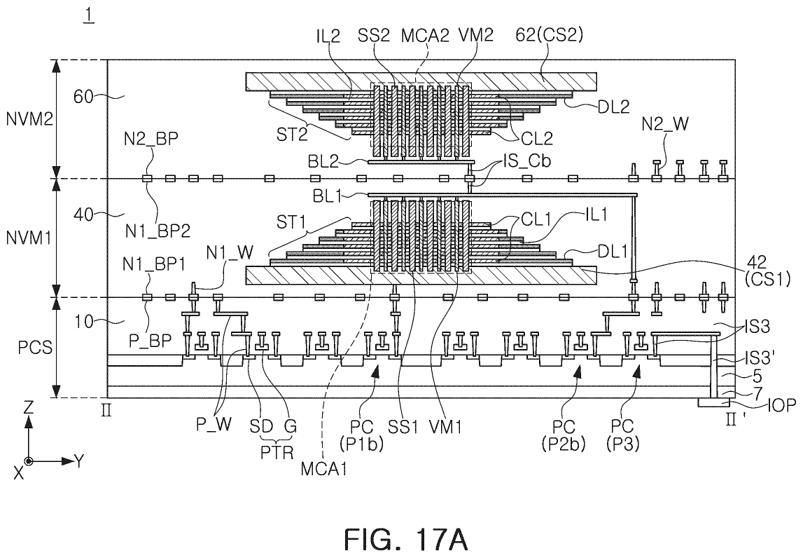

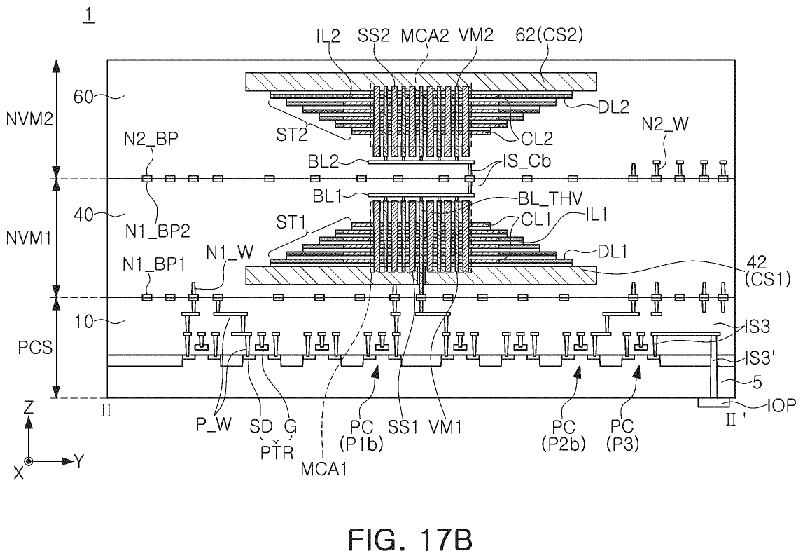

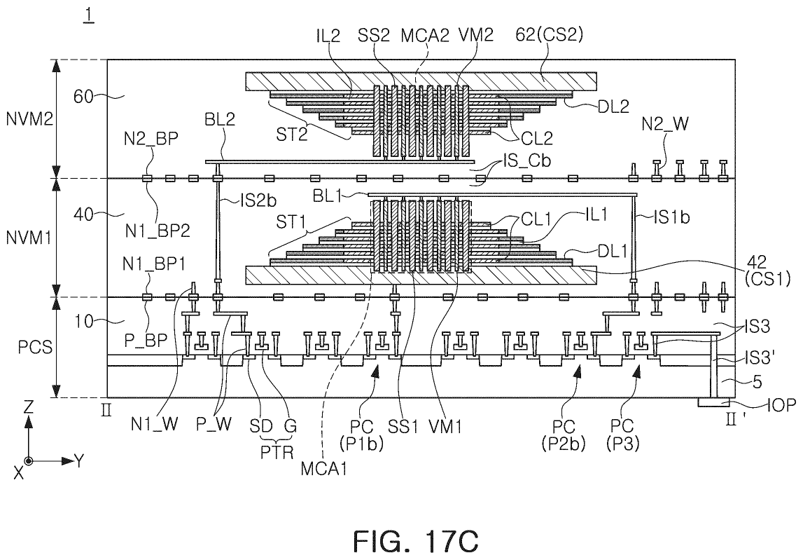

The input/output pad IOP may be disposed on the second non-volatile memory structure NVM2, but example embodiments are not limited thereto. A modified example in which the input/output pad IOP is disposed below the peripheral circuit structure PCS will be described with reference to FIG. 17A. FIG. 17A is a schematic cross-sectional view illustrating a modified example of the semiconductor device according to an example embodiment, and illustrates a cross-sectional structure corresponding to FIG. 16.

In a modified example, referring to FIG. 17A, the peripheral circuit structure PCS in FIG. 16 may further include a buffer insulating layer 7 disposed below the semiconductor substrate 5, as described with reference to FIG. 7, the input/output pad IOP may be modified to be disposed below the peripheral circuit structure PCS, and the input/output interconnection pattern IS3 (see FIG. 16) may be modified into an input/output interconnection pattern IS3′ penetrating through the semiconductor substrate 5 and the buffer insulating layer 7 and electrically connected to the peripheral circuit PC of the semiconductor substrate 5.

In FIGS. 16 and 17A, the first bit line BL1 may be electrically connected to the peripheral circuit PC via an outer side of the first stack structure ST1, but an example embodiment is not limited thereto. FIG. 17B is a schematic cross-sectional view illustrating a modified example of the semiconductor device according to an example embodiment, and illustrates a cross-sectional structure corresponding to FIG. 17A.

In a modified example, referring to FIG. 17B, the first bit line BL1 in FIGS. 16 and 17A may be electrically connected to the peripheral circuit PC through a bit line through-electrode structure BL_THV penetrating through the first stack structure ST1.

It has been described in FIGS. 15 to 17B that the first bit line BL1 and the second bit line BL2 are electrically connected to each other, but an example embodiment is not limited thereto. FIG. 17C is a schematic cross-sectional view illustrating a modified example of the semiconductor device according to an example embodiment, and illustrates a cross-sectional structure corresponding to FIG. 17A.

In a modified example, referring to FIG. 17C, the first bit line BL1 and the second bit line BL2 in FIGS. 15 to 17B may be independently electrically connected to the peripheral circuit PC. For example, the first bit line BL1 may be electrically connected to the peripheral circuit PC through a first bit line interconnection pattern IS1b, and the second bit line BL2 may be electrically connected to the peripheral circuit PC through a second bit line interconnection pattern IS2b.

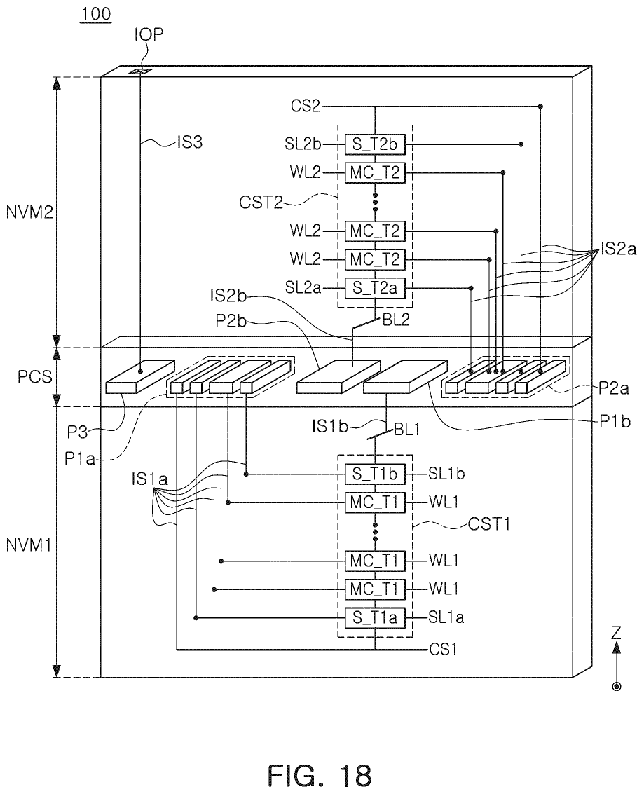

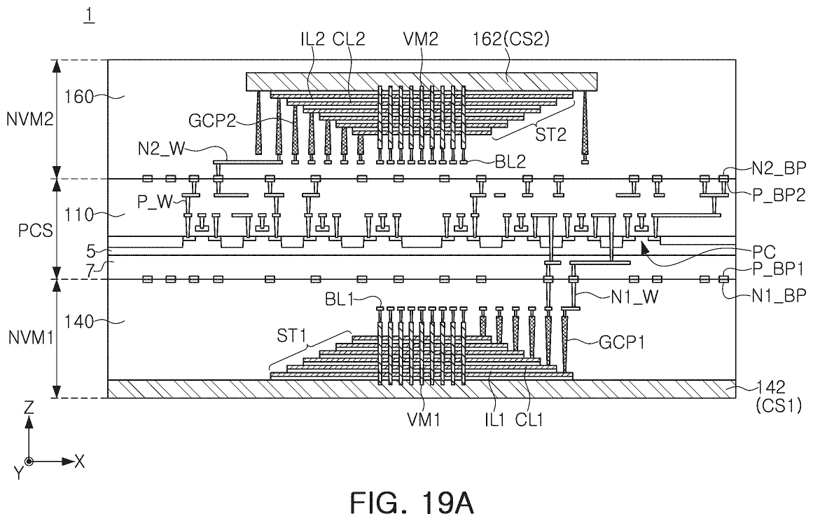

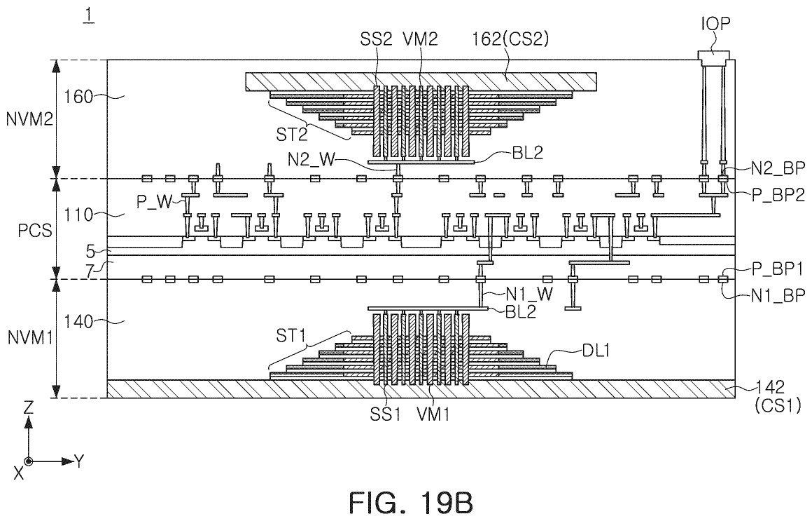

The various examples of the semiconductor device 1 described above with reference to FIGS. 1 to 17C may include the peripheral circuit structure PCS, the first non-volatile memory structure NVM1, and the second non-volatile memory structure NVM2 that are sequentially stacked. Example embodiments are not limited thereto. Modified examples of the semiconductor device described with reference to FIGS. 1 to 17C will hereinafter be described with reference to FIGS. 18 to 19B. FIGS. 18 to 19B are schematic diagrams illustrating modified examples of the semiconductor device, wherein FIG. 18 illustrates a modified example of the semiconductor device illustrated in FIG. 2, FIG. 19A illustrates a modified example of the semiconductor device illustrated in FIG. 6A, and FIG. 19B illustrates a modified example of the semiconductor device illustrated in FIG. 6B.

In a modified example, referring to FIGS. 18 to 19B, the semiconductor device 1 including the peripheral circuit structure PCS, the first non-volatile memory structure NVM1, and the second non-volatile memory structure NVM2 that are sequentially stacked in the vertical direction Z as described above with reference to FIGS. 1 to 17C may be modified into a semiconductor device 100 including a first non-volatile memory structure NVM1, a peripheral circuit structure PCS, and a second non-volatile memory structure NVM2 that are sequentially stacked in the vertical direction Z, as illustrated in FIG. 18.

The semiconductor device 100 may include interconnection structures IS1a, IS1b, IS2a, and IS2b electrically connecting the first non-volatile memory structure NVM1 and the second non-volatile memory structure NVM2 to the peripheral circuit structure PCS so as to be substantially the same as that described in FIG. 2 in terms of a circuit.

The semiconductor device 100 may further include an input/output interconnection pattern IS3 electrically connecting the input/output pad IOP and an input/output circuit of the logic circuit P3 to each other so as to be substantially the same as that described in FIG. 2 in terms of a circuit. The input/output pad IOP may be disposed on the second non-volatile memory structure NVM2.

The first non-volatile memory structure NVM1 may include a first plate pattern 142 including a first common source CS1, a first stack structure ST1 disposed on the first plate pattern 142, first vertical memory structures VM1 penetrating through the first stack structure ST1 and electrically connected to the first plate pattern 142, first bit lines BL1 electrically connected to the first vertical memory structures VM1 on the first stack structure ST1, a second insulating structure 140 covering the first stack structure ST1 and the first bit lines BL1 on the first plate pattern 142, and first bonding pads N1_BP1 embedded in an upper surface of the second insulating structure 140.

The first plate pattern 142, the first stack structure ST1, the first vertical memory structure VM1 and the first bit line BL1 may be substantially the same as the first plate pattern 42, the first stack structure ST1, the first vertical memory structure VM1, and the first bit line BL1 in FIG. 16, respectively. For example, the first stack structure ST1 may have a shape in which a width thereof decreases from the bottom to the top, and may include the first conductive lines CL1, the first interlayer insulating layers IL1 and the dummy lines DL1 described with reference to FIGS. 6A and 6B.

The first non-volatile memory structure NVM1 may further include gate contact plugs GCP1 electrically connected to the first conductive lines CL1 on the first conductive lines CL1 and connecting wirings N1_W electrically connecting the gate contact plugs GCP1 and the first bonding pads N1_BP to each other and electrically connecting the first bit lines BL1 and the first bonding pads N1_BP to each other.

The peripheral circuit structure PCS may include a semiconductor substrate 5, a rear insulating layer 7 disposed below the semiconductor substrate 5, second bonding pads P_BP1 embedded in a lower surface of the rear insulating layer 7, the peripheral circuit PC disposed on the semiconductor substrate 5, a first insulating structure 110 covering the peripheral circuit PC on the semiconductor substrate 5, third bonding pads P_BP2 embedded in an upper surface of the first insulating structure 110, and interconnection patterns P_W electrically connecting the peripheral circuit PC and the second and third bonding pads P_BP1 and P_BP2 to each other.

The second non-volatile memory structure NVM2 may include a second stack structure ST2 including the second conductive lines CL2, the second interlayer insulating layers IL2, and the second dummy lines DL2 as described with reference to FIGS. 6A and 6B, a second plate pattern 162 including a second common source CS2 on the second stack structure ST2, second vertical memory structures VM2 penetrating through the second stack structure ST2 and electrically connected to the second plate pattern 162, second bit lines BL2 electrically connected to the second vertical memory structures VM2 under the second stack structure ST2, a third insulating structure 160, fourth bonding pads N2_BP embedded in a lower surface of the third insulating structure 160, and interconnection patterns N2_W electrically connecting the second conductive lines CL2, the second plate pattern 162, and the second vertical memory structures VM2 to the fourth bonding pads N2_BP.

A structure including the second stack structure ST2, the second plate pattern 162, the second vertical memory structures VM2, the second bit lines BL2, and the interconnection patterns N2_W may be embedded in the third insulating structure 160.

The fourth bonding pads N2_BP may be bonded to the third bonding pads P_BP2 while being in contact with the third bonding pads P_BP2.

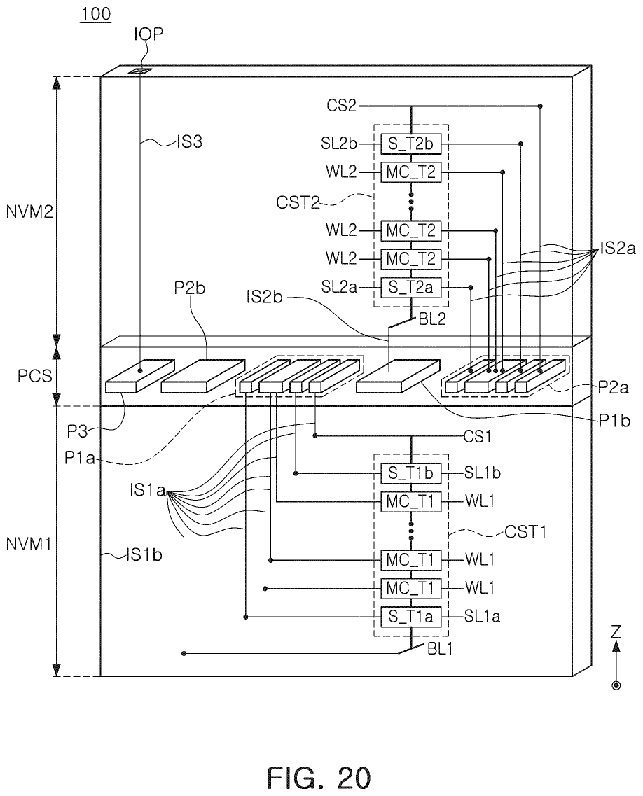

Modified examples of the semiconductor device described with reference to FIG. 18 will be described with reference to FIGS. 20 to 22. FIGS. 20 to 22 are schematic diagrams illustrating modified examples of the semiconductor device according to an example embodiment, and illustrate modified examples of the semiconductor device illustrated in FIG. 2.

In a modified example, referring to FIG. 20, the first common source CS1 in FIG. 18 may be modified to be disposed above the first upper select transistor ST_1b, and the first bit line BL1 in FIG. 18 may be modified to be disposed below the first lower select transistor ST_1a.

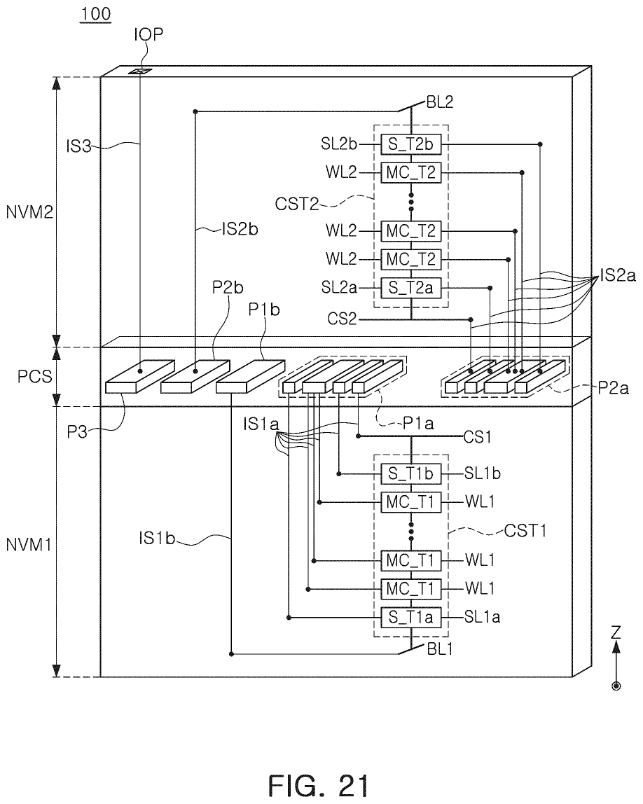

In a modified example, referring to FIG. 21, as in FIG. 20, the first common source CS1 in FIG. 18 may be modified to be disposed above the first upper select transistor ST_1b, and the first bit line BL1 in FIG. 18 may be modified to be disposed below the first lower select transistor ST_la. In addition, the second common source CS2 in FIG. 18 may be modified to be disposed below the second lower select transistor ST_2a, and the second bit line BL2 in FIG. 18 may be modified to be disposed above the second upper select transistor ST_2b.

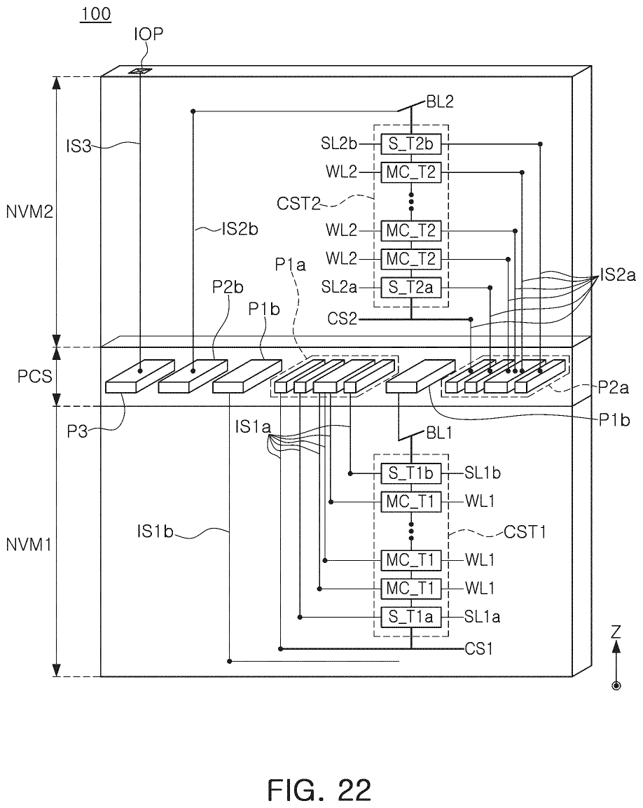

In a modified example, referring to FIG. 22, the second common source CS2 in FIG. 18 may be modified to be disposed below the second lower select transistor ST_2a, and the second bit line BL2 in FIG. 18 may be modified to be disposed above the second upper select transistor ST_2b.

Various examples in which the three chips are stacked and bonded to each other to constitute one chip in the semiconductor device as described with reference to FIG. 5A have been described with reference to FIGS. 1 to 22, but an example embodiment is not limited thereto, and may be variously modified.

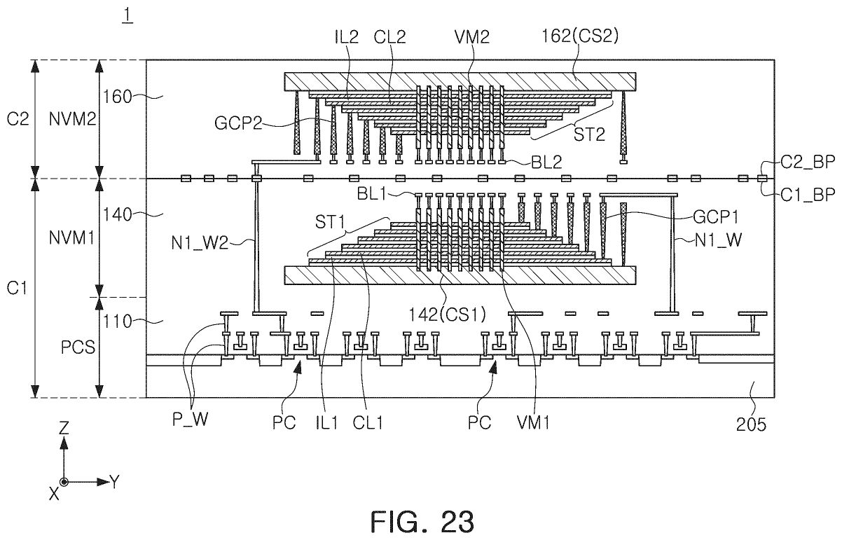

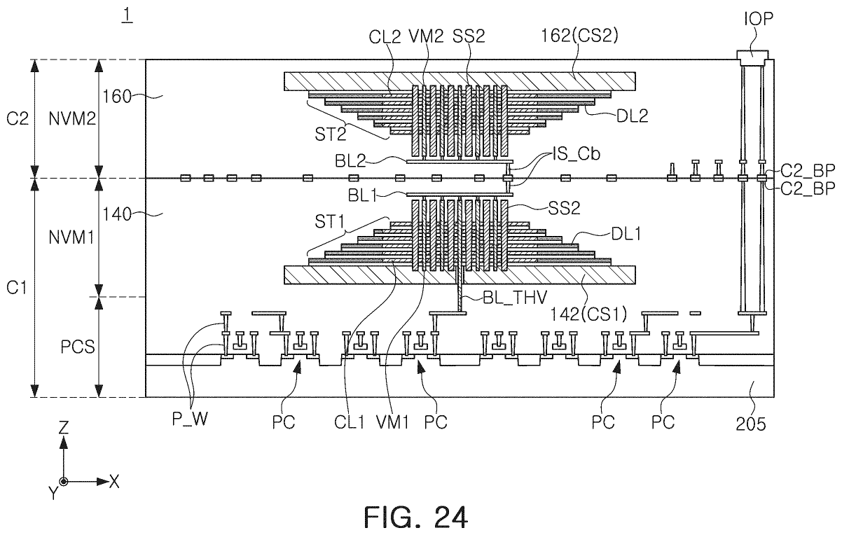

An illustrative example in which the peripheral circuit structure PCS and the first non-volatile memory structure NVM1 constitute a first chip, the second non-volatile memory structure NVM2 constitutes a second chip bonded to the first chip, and a semiconductor chip is formed by bonding two stacked chips to each other will hereinafter be described with reference to FIGS. 23 and 24. FIG. 23 is a schematic cross-sectional view illustrating a region taken along line I-I′ of FIG. 1, and FIG. 24 is a schematic cross-sectional view illustrating a region taken along line II-IP of FIG. 1. FIGS. 23 and 24 are cross-sectional views of a semiconductor device modified from the semiconductor device illustrated in FIG. 15.

In a modified example, referring to FIGS. 23 and 24 together with FIGS. 1 and 15, a first chip C1 may include the peripheral circuit structure PCS and the first non-volatile memory structure NVM1 stacked in the vertical direction, and the second chip C2 may include the second non-volatile memory structure NVM2.

In the first chip Cl (see FIGS. 23 and 24) including the peripheral circuit structure PCS and the first non-volatile memory structure NVM1 in FIG. 15, the peripheral circuit structure PCS may include a semiconductor substrate 205, the peripheral circuit PC disposed on the semiconductor substrate 205, and peripheral interconnection patterns P_W disposed on the peripheral circuit PC, and the first non-volatile memory structure NVM1 may include a first plate pattern 142 including a first common source CS1, a first stack structure ST1 disposed on the first plate pattern 142, first vertical memory structures VM1 penetrating through the first stack structure ST1 and electrically connected to the first plate pattern 142, and first bit lines BL1 electrically connected to the first vertical memory structures VM1 on the first stack structure ST1.

The first stack structure ST1 may include the first conductive lines CL1, the first interlayer insulating layers IL1 and the first dummy lines DL1 as described above.

The first chip C1 may further include a first insulating structure 140 and first chip bonding pads C1_BP embedded in an upper surface of the first insulating structure 140. The first insulating structure 140 may cover the peripheral circuit PC, the peripheral interconnection patterns P_W, the first plate pattern 142, the first stack structure ST1, the first vertical memory structures VM1, and the first bit lines BL1 on the semiconductor substrate 205.

The second non-volatile memory structure NVM2 of the second chip C2 may be substantially the same as the second non-volatile memory structure NVM2 described with reference to FIGS. 6A and 6B. The fourth bonding pads N2_BP described with reference to FIGS. 6A and 6B may be referred to as second chip bonding pads C2_BP in FIGS. 23 and 24.

The first chip bonding pads C1_BP and the second chip bonding pads C2_BP may be bonded to each other while being in contact with each other.

The semiconductor device 1 according to an example embodiment may include a common bit line interconnection pattern IS_Cb electrically connecting the first bit line BL1 and the second bit line BL2 to each other as described with reference to FIG. 16.

The first bit line BL1 may be electrically connected to the peripheral circuit PC through a bit line through-electrode structure BL_THV penetrating through the first stack structure ST1.

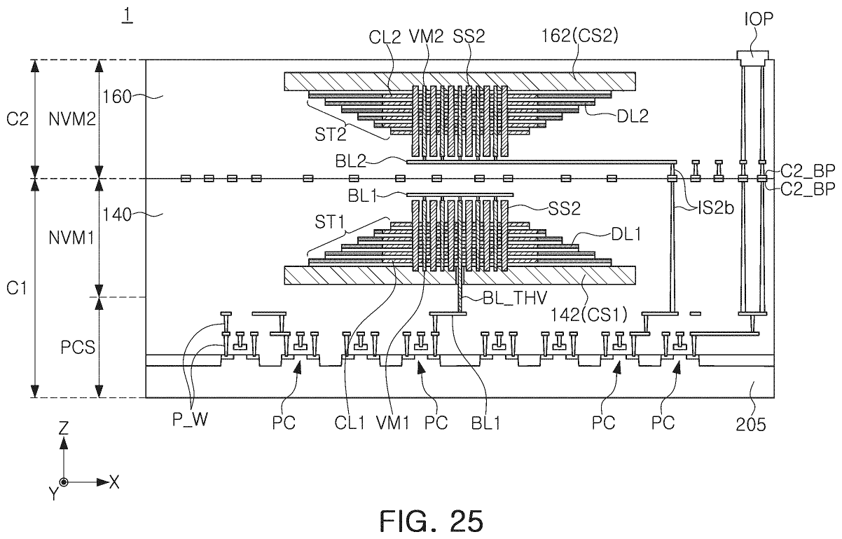

It has been described in FIGS. 22 and 24 that the first bit line BL1 and the second bit line BL2 are electrically connected to each other, but an example embodiment is not limited thereto. FIG. 25 is a schematic cross-sectional view illustrating a modified example of the semiconductor device according to an example embodiment, and illustrates a cross-sectional structure corresponding to FIG. 24.

In a modified example, referring to FIG. 25, the first bit line BL1 and the second bit line BL2 in FIGS. 23 and 24 may be independently electrically connected to the peripheral circuit PC. For example, the first bit line BL1 may be electrically connected to the peripheral circuit PC through a bit line through-electrode structure BL_THV penetrating through the first stack structure ST1, and the second bit line BL2 may be electrically connected to the peripheral circuit PC through a second bit line interconnection pattern IS2b.

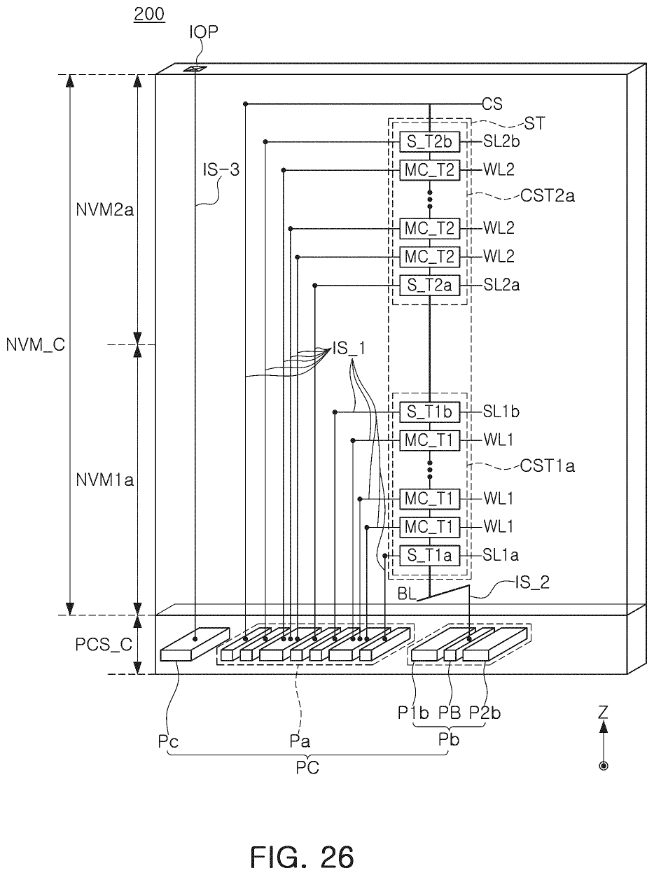

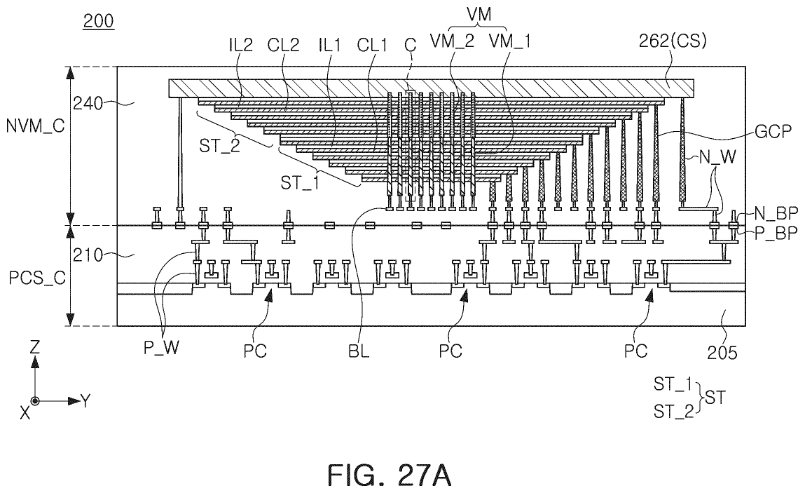

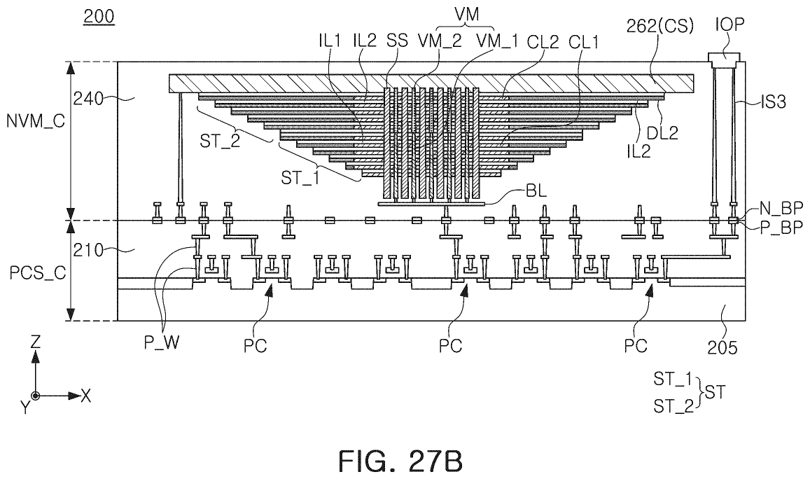

Next, an illustrative example in which the peripheral circuit structure PCS described above constitutes a first chip PCS_C, the first non-volatile memory structure NVM1a and the second non-volatile memory structure NVM2a constitute a second chip NVM_C bonded to the first chip, and a semiconductor chip is formed by bonding two stacked chips to each other will hereinafter be described with reference to FIGS. 26 to 27B. FIG. 27A is a schematic cross-sectional view illustrating a region taken along line I-I′ of FIG. 1, and FIG. 27B is a schematic cross-sectional view illustrating a region taken along line II-II′ of FIG. 1.

In a modified example, referring to FIGS. 26 to 27B together with FIG. 1, a semiconductor device 200 according to a modified example may include a first chip PCS_C and a second chip NVM_C bonded to the first chip PCS_C. The peripheral circuit structure PCS (see FIGS. 6A and 6B) described above may constitute the first chip PCS_C. Accordingly, the first chip PSC_C may be substantially the same as the peripheral circuit structure PCS described with reference to FIGS. 6A and 6B.

The second chip NVM_C may include a bit line BL, a common source CS, and a memory cell string ST between the bit line BL and the common source CS in terms of a circuit. The memory cell string ST may include a first memory cell string CST1a that is substantially the same as the first memory cell string CST1 described with reference to FIG. 2 and a second memory cell string CST2a that is substantially the same as the second memory cell string CST2 described with reference to FIG. 2. The second memory cell string CST2a may be disposed on the first memory cell string CST1a.

The semiconductor device 200 may further include interconnection structures IS_1 electrically connecting the bit line BL, the common source CS, and the memory cell string ST to the peripheral circuit PC.

The peripheral circuit PC may include a circuit Pb including the first and second peripheral circuits P1b and P2b and the distribution circuit PB as described with reference to FIG. 15. Such a circuit Pb may be electrically connected to the bit line BL through a bit line interconnection pattern IS_2. The distribution circuit PB may perform the same role as the role described with reference to FIG. 15.

The semiconductor device 200 may further include an input/output pad IOP and an input/output interconnection pattern IS_3 electrically connecting the input/output pad IOP and the peripheral circuit PC to each other.

The second chip NVM_C may include a stack structure ST, a plate pattern 262 including a common source CS on the stack structure ST, vertical memory structures VM penetrating through the stack structure ST, and separation structures SS penetrating through the stack structure ST and defining memory blocks.

The stack structure ST may include a first stack structure ST_1 and a second stack structure ST_2 disposed on the first stack structure ST_1.

The first stack structure ST_1 may include the first conductive lines CL1, the first interlayer insulating layers ILL and the first dummy lines DL as described above, and the second stack structure ST_2 may include the second conductive lines CL2, the second interlayer insulating layers IL2, and the second dummy lines DL as described above.

The stack structure ST may have a shape in which a width thereof increases from the bottom toward the top.

The vertical memory structure VM may include a first vertical memory structure VM_1 penetrating through the first stack structure ST_1 and a second vertical memory structure VM_2 penetrating through the second stack structure ST_2.

The first vertical memory structure VM_1 and the second vertical memory structure VM_2 may be connected to each other in the vertical direction Z.

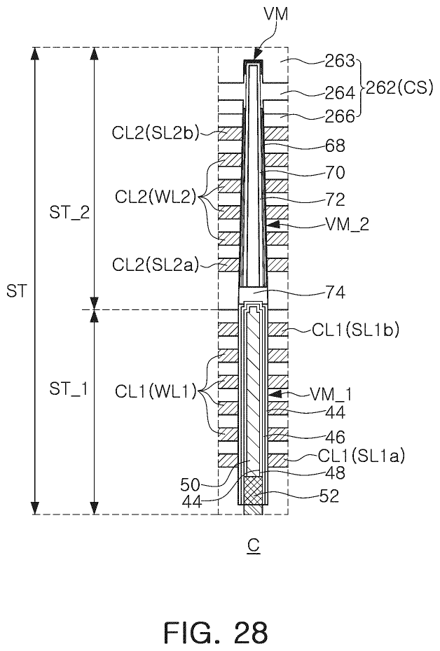

An example of the vertical memory structure VM will be described with reference to FIG. 28. FIG. 28 is a partially enlarged view of a region indicated by ‘C’ in FIG. 27A.

Referring to FIG. 28, the first vertical memory structure VM_1 may include an insulating core region 50, a data storage structure 48 surrounding side surfaces of the insulating core region 50, a channel layer 46 surrounding outer side surfaces of the data storage structure 48, a gate dielectric layer 44 surrounding outer side surfaces of the channel layer 46, and a pad pattern 52 in contact with the channel layer 46 below the insulating core region 50, similar to the first vertical memory structure VM1 described with reference to FIG. 8A.

The data storage structure 48 may be the data storage structure of the first vertical memory structure VM1 described with reference to FIG. 8A.

The second vertical memory structure VM_2 may include an insulating core region 72, a channel layer 70 covering at least side surfaces of the insulating core region 72, a data storage structure 68 covering at least outer side surfaces of the channel layer 70, and a pad pattern 74 in contact with the channel layer 70 below the insulating core region 72, similar to the second vertical memory structure VM2 described with reference to FIG. 8B.

The data storage structure 68 of the second vertical memory structure VM_2 may be the data storage structure of the second vertical memory structure VM2 described with reference to FIG. 8B.

The plate pattern 262 may be substantially the same as the plate pattern 62 of FIG. 8B. For example, the second plate pattern 262 may include a first pattern layer 263, a second pattern layer 264 disposed below the first pattern layer 263, and a third pattern layer 266 disposed below the second pattern layer 264. At least one of the first pattern layer 263, the second pattern layer 264, and the third pattern layer 266 may include a polysilicon layer, for example, a polysilicon layer having a conductivity-type of an N-type. The second vertical memory structure VM_2 may penetrate through the second and third pattern layers 264 and 266 and may be in contact with the first pattern layer 263. The second pattern layer 264 may penetrate through the data storage structure 68 and may be in contact with the channel layer 70.

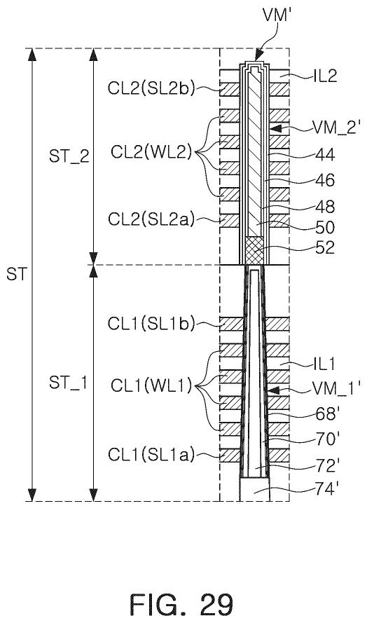

A modified example of the vertical memory structure VM will be described with reference to FIG. 29. FIG. 29 is a partially enlarged view of a region indicated by ‘C’ in FIG. 27A.

In a modified example, referring to FIG. 29, a first vertical memory structure VM_1′ may include an insulating core region 72′, a channel layer 70′ covering side surfaces and an upper surface of the insulating core region 72′, a data storage structure 68′ covering outer side surfaces of the channel layer 70′, and a pad pattern 74′ in contact with the channel layer 70′ below the insulating core region 72′, similar to the second vertical memory structure VM2 described with reference to FIG. 8B.

The data storage structure 68′ of the first vertical memory structure VM_1′ may be the data storage structure of the second vertical memory structure VM2 described with reference to FIG. 8B.

The second vertical memory structure VM_2′ may include an insulating core region 50, a data storage structure 48 surrounding side surfaces of the insulating core region 50, a channel layer 46 surrounding outer side surfaces of the data storage structure 48, a gate dielectric layer 44 surrounding outer side surfaces of the channel layer 46, and a pad pattern 52 in contact with the channel layer 46 below the insulating core region 50, similar to the first vertical memory structure VM1 described with reference to FIG. 8A.

The data storage structure 48 of the second vertical memory structure VM_2′ may be the data storage structure of the first vertical memory structure VM1 described with reference to FIG. 8A.

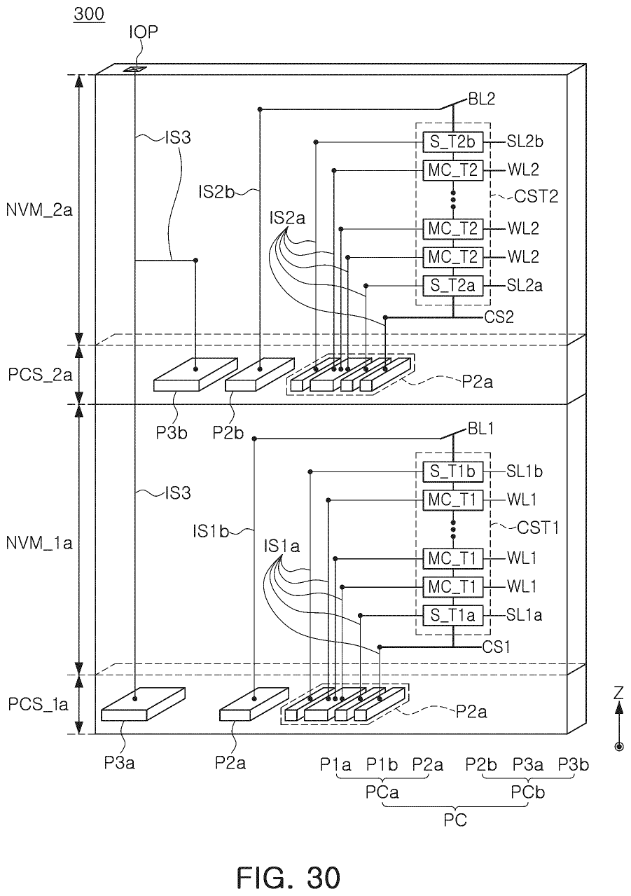

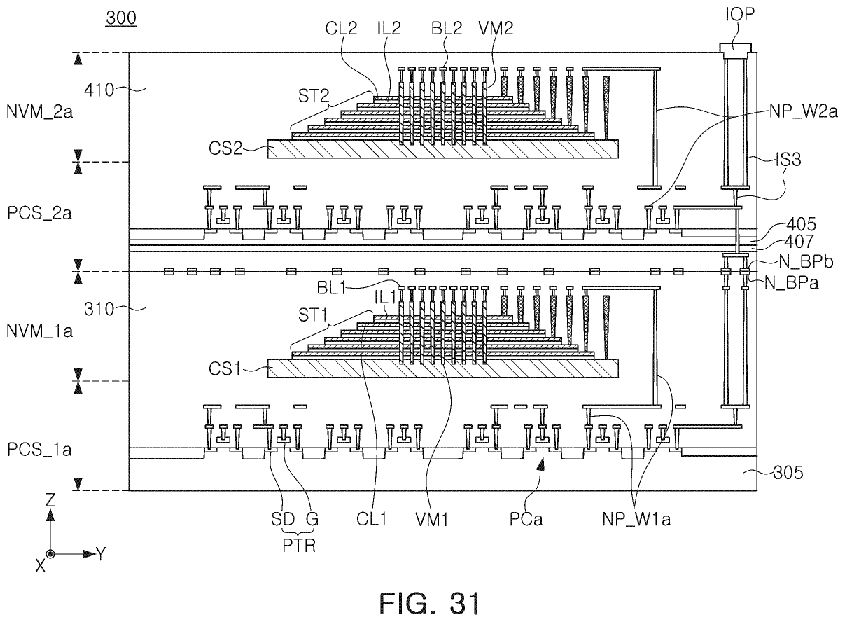

Next, a modified example of the peripheral circuit structure PCS described above will be described with reference to FIGS. 30 and 31.

Referring to FIGS. 30 and 31, the peripheral circuit structure PCS described above may include a first peripheral circuit structure PCS_1a disposed below the first non-volatile memory structure NVM_1a and a second peripheral circuit structure PCS_2a disposed between the first non-volatile memory structure NVM1a and the second non-volatile memory structure NVM2a.

The first peripheral circuit structure PCS_1a and the first non-volatile memory structure NVM_1a may constitute one first chip, and the second peripheral circuit structure PCS_2a and the second non-volatile memory structure NVM_2a may constitute one second chip.

First bonding pads N_BPa of the first chip PCS_1a and NVM_1a and second bonding pads N_BPb of the second chip PCS_2a and NVM_2a may be bonded to each other while being in contact with each other.

In the first chip PCS_1a and NVM_1a, the first peripheral circuit structure PCS_1a may include a semiconductor substrate 305, a first peripheral circuit PCa disposed on the semiconductor substrate 305, and peripheral interconnection patterns NP_Wla disposed on the first peripheral circuit PCa, and the first non-volatile memory structure NVM_1a may include a first common source CS1, a first stack structure ST1 disposed on the first common source CS1, first vertical memory structures VM1 penetrating through the first stack structure ST1 and electrically connected to the first common source CS1, and first bit lines BL1 electrically connected to the first vertical memory structures VM1 on the first stack structure ST1.

The first stack structure ST1 may include the first conductive lines CL1 and the first interlayer insulating layers IL1 as described above. The first chip PCS_1a and NVM_1a may include a first insulating structure 310 and the first bonding pads N_BPa embedded in an upper surface of the first insulating structure 310.

In the second chip PCS_2a and NVM_2a, the second peripheral circuit structure PCS_2a may include a semiconductor substrate 405, a rear insulating layer 407 disposed below the semiconductor substrate 405, the second bonding pads N_BPb embedded in a lower surface of the rear insulating layer 407, a second peripheral circuit PCb disposed on the semiconductor substrate 405, and peripheral interconnection patterns NP_W2a disposed on the second peripheral circuit PCb, and the second non-volatile memory structure NVM_2a may include a second common source CS2, a second stack structure ST2 disposed on the second common source CS2, second vertical memory structures VM2 penetrating through the second stack structure ST2 and electrically connected to the second common source CS2, and second bit lines BL2 electrically connected to the second vertical memory structures VM2 on the second stack structure ST2.

The second stack structure ST2 may include the second conductive lines CL2 and the second interlayer insulating layers IL1 as described above.

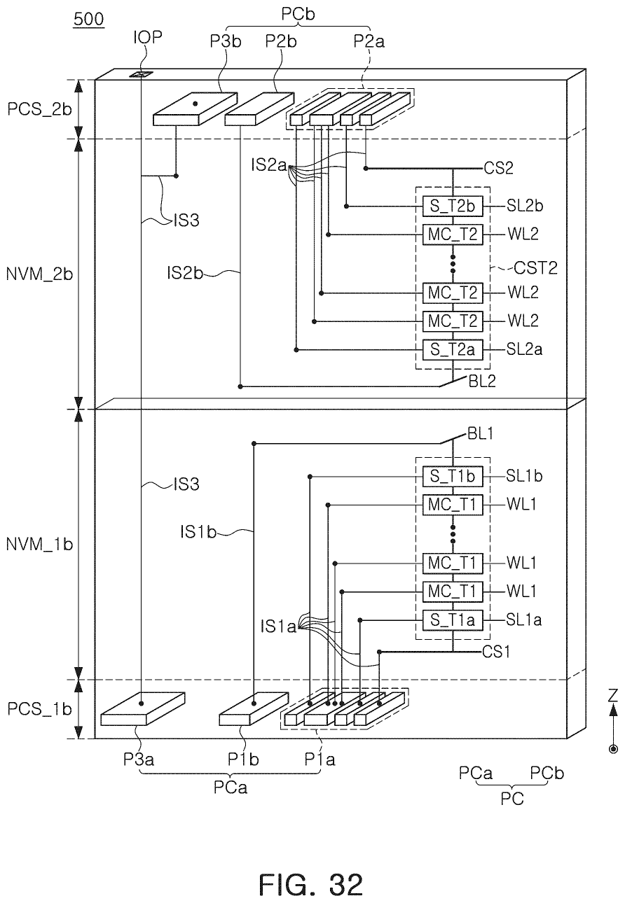

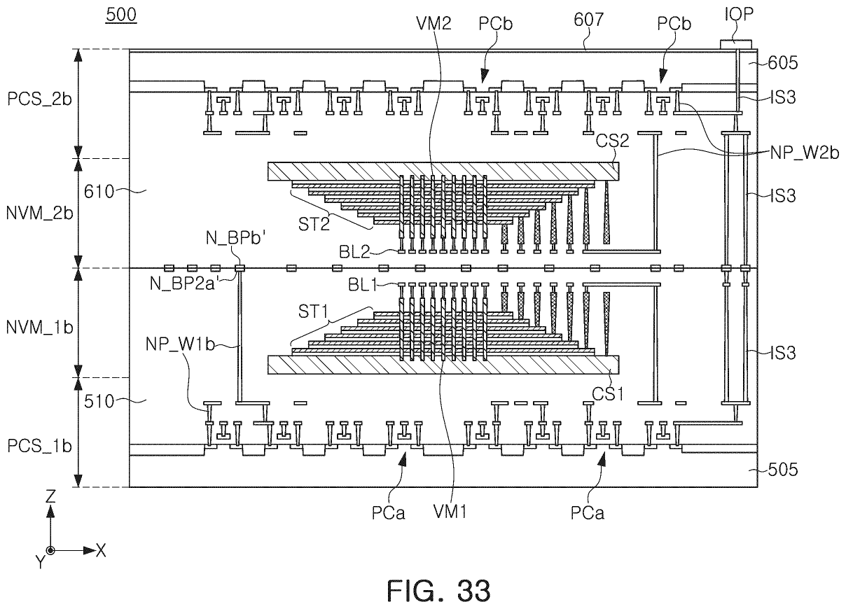

Next, a modified example of the peripheral circuit structure PCS described above will be described with reference to FIGS. 32 and 33.

Referring to FIGS. 32 and 33, the peripheral circuit structure PCS described above may include a first peripheral circuit structure PCS_1b disposed below the first non-volatile memory structure NVM_1b and a second peripheral circuit structure PCS_2b disposed above the second non-volatile memory structure NVM2b.

The first peripheral circuit structure PCS_1b and the first non-volatile memory structure NVM_1b may constitute one first chip, and the second peripheral circuit structure PCS_2b and the second non-volatile memory structure NVM_2b may constitute one second chip.

The first peripheral circuit structure PCS_1b and first non-volatile memory structure NVM_1b may constitute one first chip and may be substantially the same as the first peripheral circuit structure PCS_1a and NVM_1a described with reference to FIGS. 30 and 31, respectively. The first peripheral circuit structure PCS_1b and first non-volatile memory structure NVM_1b may include a semiconductor substrate 505, a first insulating structure 510, first vertical memory structures VM1, and bonding pads N_BP2a′.

In the second chip PCS_2b and NVM_2b, the second peripheral circuit structure PCS_2b may include a semiconductor substrate 605, a second peripheral circuit PCb disposed below the semiconductor substrate 605, and a buffer insulating layer 607 disposed on the semiconductor substrate 605, and the second non-volatile memory structure NVM_2b may include a second common source CS2, a second stack structure ST2 disposed below the second common source CS2, second vertical memory structures VM2 penetrating through the second stack structure ST2 and electrically connected to the second common source CS2, and second bit lines BL2 electrically connected to the second vertical memory structures VM2 below the second stack structure ST2. The second stack structure ST2 may include the second conductive lines CL2 and the second interlayer insulating layers IL1 as described above. The second chip PCS_2b and NVM_2b may further include bonding pads N_BPb′ electrically connected to the bonding pads N_BP2a′ of the first chip PCS_1b and NVM_1b.

The input/output pad IOP may be disposed on the buffer insulating layer 607.

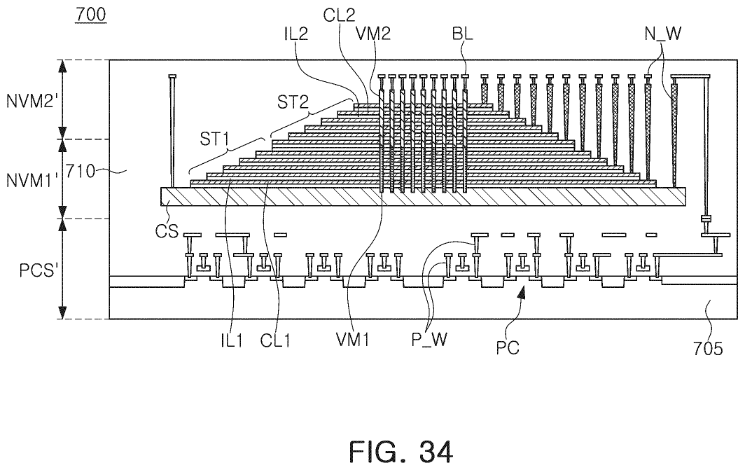

As described above with reference to FIG. 5A, the peripheral circuit structure PCS, the first non-volatile memory structure NVM1 and the second non-volatile memory structure NVM2 may constitute one semiconductor chip CH. An illustrative example in which the peripheral circuit structure PCS, the first non-volatile memory structure NVM1 and the second non-volatile memory structure NVM2 constitute one semiconductor chip CH as described above will be described with reference to FIG. 34.

Referring to FIG. 34, a semiconductor device 700 according to a modified example may include one semiconductor chip including a peripheral circuit structure PCS′, a first non-volatile memory structure NVM1′, a second non-volatile memory structure NVM2′ that are sequentially stacked. A mold layer 710 may cover the peripheral circuit structure PCS′, a first non-volatile memory structure NVM1′, and second non-volatile memory structure NVM2′.

The peripheral circuit structure PCS′ may include a semiconductor substrate 705, a peripheral circuit PC disposed on the semiconductor substrate 705, and peripheral interconnection patterns P_W electrically connected to the peripheral circuit PC on the semiconductor substrate 705.

The semiconductor device 700 may include a common source CS, bit lines BL disposed on the common source CS, stack structures ST1 and ST2 disposed between the common source CS and the bit lines BL, and vertical memory structures VM1 and VM2 penetrating through the stack structures ST1 and ST2. As described with reference to FIGS. 27A and 27B, the stack structure ST1 and ST2 may include a first stack structure ST1 and a second stack structure ST2 disposed on the first stack structure ST1.

The stack structures ST1 and ST2 may have a shape in which widths thereof decreases from the bottom toward the top.

The vertical memory structures VM1 and VM2 may include a first vertical memory structure VM1 penetrating through the first stack structure ST_1 and a second vertical memory structure VM2 penetrating through the second stack structure ST_2. The first vertical memory structure VM1 and the second vertical memory structure VM2 may be connected to each other while being in contact with each other in the vertical direction Z.

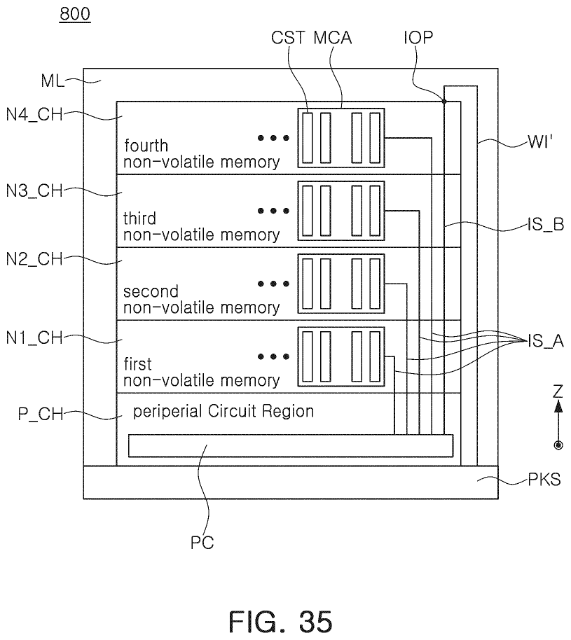

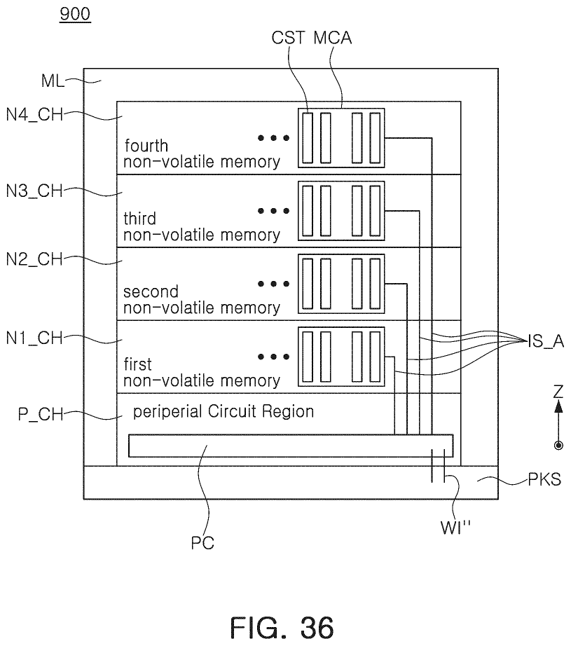

In the various examples of the semiconductor devices described above with reference to FIGS. 1 to 34, two different first and second non-volatile memory structures have been mainly described, but an example embodiment is not limited thereto. For example, the semiconductor device may include three or more non-volatile memory structures stacked in the vertical direction Z. Illustrative examples of the semiconductor device including the three or more non-volatile memory structures as described above will be described with reference to FIGS. 35 and 36.

Referring to FIG. 35, a semiconductor device 800 may include a package substrate PKS, first to fourth non-volatile memory structures N1_CH, N2_CH, N3_CH, and N4_CH sequentially stacked in the vertical direction Z on the package substrate PKS, a molded layer ML covering the first to fourth non-volatile memory structures N1_CH, N2_CH, N3_CH, and N4_CH on the package substrate PKS.

The semiconductor device 800 may further include a peripheral circuit structure P_CH including a peripheral circuit PC between the package substrate PKS and the first non-volatile memory structure N_CH.

Each of the first to fourth non-volatile memory structures N1_CH, N2_CH, N3_CH, and N4_CH may include a memory cell array region MCA including memory cell strings ST.

The first to fourth non-volatile memory structures N1_CH, N2_CH, N3_CH, and N4_CH may be at least two types of non-volatile memories. For example, the first to fourth non-volatile memory structures N1_CH, N2_CH, N3_CH, and N4_CH may include at least two different types of data storage structures of a data storage structure of a flash memory, a data storage structure of a ReRAM, a data storage structure of a PRAM, and a data storage structure of an FeRAM. For example, one or more of the first to fourth non-volatile memory structures N1_CH, N2_CH, N3_CH, and N4_CH may include a data storage structure of a flash memory, and one or more of the others of the first to fourth non-volatile memory structures N1_CH, N2_CH, N3_CH, and N4_CH may include a data storage structure of a ReRAM, a data storage structure of a PRAM, or a data storage structure of an FeRAM.

The memory cell array area MCA including the memory cell strings ST of each of the first to fourth non-volatile memory structures N1_CH, N2_CH, N3_CH, and N4_CH may be electrically connected to the peripheral circuit PC through interconnection structures IS_A penetrating through the first to fourth non-volatile memory structures N1_CH, N2_CH, N3_CH, and N4_CH.

The first peripheral circuit structure P_CH and the first to fourth non-volatile memory structures N1_CH, N2_CH, N3_CH, and N4_CH may constitute one semiconductor chip. The semiconductor chip may include an input/output pad IOP. The input/output pad IOP may be electrically connected to an input/output circuit of the peripheral circuit PC through an interconnection structure IS_B penetrating through the first to fourth non-volatile memory structures N1_CH, N2_CH, N3_CH, and N4_CH.

The semiconductor device 800 may further include an interconnection structure WI′ electrically connected to the package substrate PKS through the input/output pad IOP. The interconnection structure WI′ may have the form of a bonding wire as described with reference to FIG. 5B.

Referring to FIG. 36, in a semiconductor device 900, the interconnection structure WI' having the form of the bonding wire described with reference to FIG. 35 may be modified into an interconnection structure WI″ connecting a semiconductor chip including the first peripheral circuit structure P_CH and the first to fourth non-volatile memory structures N1_CH, N2_CH, N3_CH, and N4_CH and the package substrate PKS to each other in a bump connection manner of a flip chip structure or a direct bonding manner.

In FIG. 35 or 36, the semiconductor chip P_CH, N1_CH, N2_CH, N3_CH, and N4_CH including the first peripheral circuit structure P_CH and the first to fourth non-volatile memory structures N1_CH, N2_CH, N3_CH, and N4_CH may include a plurality of chips bonded to each other by intermetallic bonding.

The first peripheral circuit structure P_CH and the first to fourth non-volatile memory structures N1_CH, N2_CH, N3_CH, and N4_CH may include two chips, three chips, four chips, or five chips. For example, the first peripheral circuit structure P_CH may be a first chip, the first to fourth non-volatile memory structures N1_CH, N2_CH, N3_CH, and N4_CH may be second to fifth chips, and the first to fifth chips may be bonded to each other by intermetallic bonding to form one semiconductor chip P_CH, N1_CH, N2_CH, N3_CH, and N4_CH.

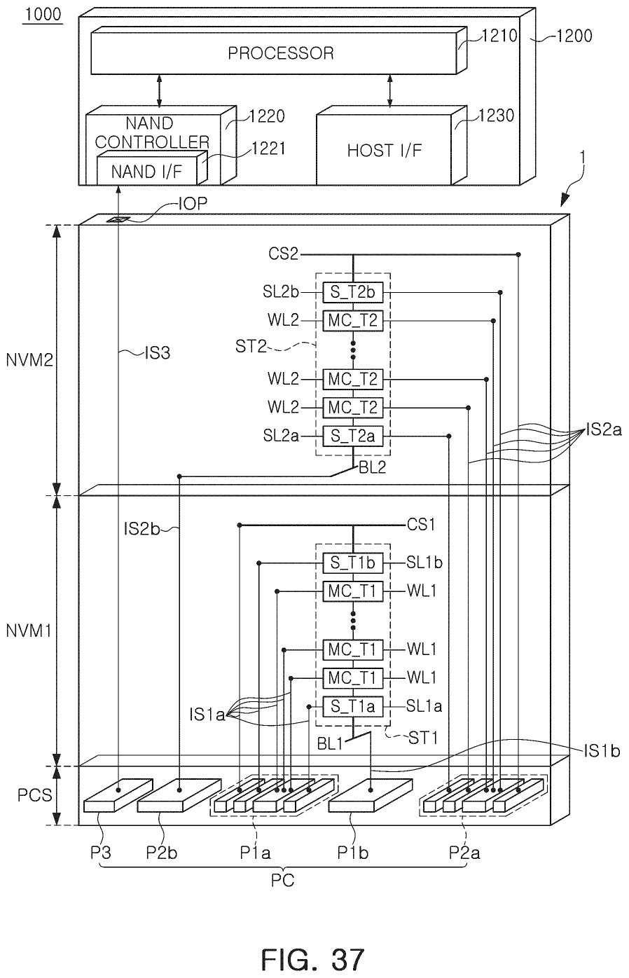

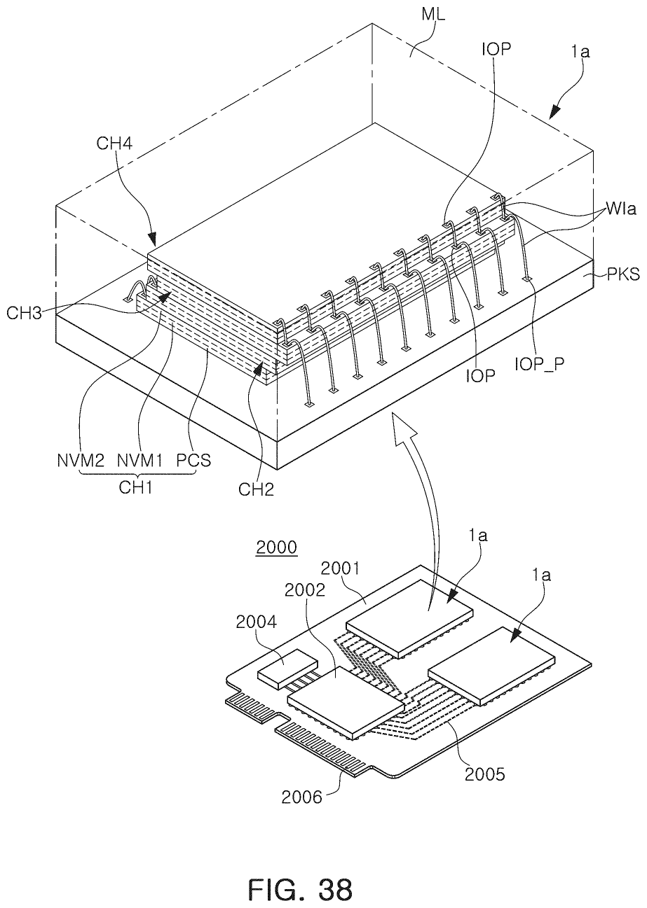

Next, a system including the semiconductor device according to an example embodiment will be described with reference to FIGS. 37 and 38.

FIG. 37 is a schematic diagram illustrating a system including the semiconductor device according to an example embodiment.

Referring to FIG. 37, a system 1000 according to an example embodiment may include the semiconductor device described above, for example, the semiconductor device 1 described above with reference to FIGS. 1 and 2 and a controller 1200 electrically connected to the semiconductor device to control the semiconductor device 1. The system 1000 may be a storage device including the semiconductor device 1 or an electronic device including the storage device. For example, the system 1000 may be a solid state drive (SSD) device, a universal serial bus (USB), a computing system, a medical device, a communications device, or a vehicle system including the semiconductor device 1.

In an example embodiment, the system 1000 may be an electronic system or a data storage system storing data.

The semiconductor device 1 may communicate with the controller 1200 through the input/output pad IOP. The controller 1200 may be electrically connected to the semiconductor device 1000 through the input/output pad IOP, and may control the semiconductor device 1000.

The controller 1200 may include a processor 1210, a NAND controller 1220, and a host interface 1230. According to example embodiments, the system 1000 may include a plurality of semiconductor devices 1, and in this case, the controller 1200 may control the plurality of semiconductor devices 1.

The processor 1210 may control a general operation of the system 1000 including the controller 1200. The processor 1210 may operate according to desired and/or alternatively predetermined firmware, and may access the semiconductor device 1 by controlling the NAND controller 1220. The NAND controller 1220 may include a NAND interface 1221 processing communications with the semiconductor device 1. A control command for controlling the semiconductor device 1, data to be written to the memory cell transistors MC_T1 and MC_T2 of the semiconductor device 1, data to be read from the memory cell transistors MC_T1 and MC_T2 of the semiconductor device 1, and the like, may be transmitted through the NAND interface 1221. The host interface 1230 may provide a communications function between the system 1000 and an external host. When the control command is received from the external host through the host interface 1230, the processor 1210 may control the semiconductor device 1 in response to the control command

It has been illustrated in FIG. 37 that the semiconductor device 1 is the semiconductor device illustrated in FIG. 2, but an example embodiment is not limited thereto. For example, the semiconductor device 1 may be a semiconductor device according to any one of the various example embodiments described with reference to FIGS. 1 to 36 or a semiconductor device according to a combination of the various example embodiments.

A portable data storage device, a vehicle data storage device, or a data storage device of a data center including the semiconductor device 1 as described above may be provided. For example, in a solid state drive (SSD) device, when an ambient temperature is high or a voltage is unstable, information stored in a buffer memory such as a dynamic random access memory (DRAM) may be stored in a non-volatile memory (for example, one of a ReRAM, an FeRAM, and a PRAM) having a fast operating speed among different types of non-volatile memory structures through a controller, such that loss of the information stored in the buffer memory may be limited and/or prevented. Accordingly, the semiconductor device 1 capable of limiting and/or preventing some data from being lost due to an unstable surrounding environment and the system 1000 including the same may be provided.

In an example embodiment, when the system 1000 is a vehicle data storage system, information required for autonomous driving that needs to be quickly read and written may be stored in a non-volatile memory having a fast operating speed (e.g., one of a ReRAM, an FeRAM, and a PRAM) among different types of non-volatile memory structures, and general data such as a black box image may be stored in a non-volatile memory (e.g., a flash memory) that is stabler or is capable of storing a large-capacity information. Accordingly, a vehicle or a vehicle data storage system capable of realizing stable autonomous driving and storing stable surrounding information may be provided.

FIG. 38 is a schematic perspective view of the system including the semiconductor device according to an example embodiment.

Referring to FIG. 38, a data storage system 2000 according to an example embodiment may include a main board 2001 and a controller 2002, one or more semiconductor devices such as the semiconductor device la as described with reference to FIG. 5B, and a dynamic random access memory (DRAM) 2004 that are mounted on the main board 2001. The semiconductor device la may be a semiconductor package. The semiconductor device la and the DRAM 2004 may be connected to the controller 2002 by wiring patterns 2005 formed on the main board 2001.

The main board 2001 may include a connector 2006 including a plurality of pins coupled to an external host. The number and an arrangement of pins in the connector 2006 may vary depending on a communications interface between the data storage system 2000 and the external host. In example embodiments, the data storage system 2000 may communicate with the external host according to any one of interfaces such as universal serial bus (USB), peripheral component interconnect express (PCI-Express), serial advanced technology attachment (SATA), and M-PHY for universal flash storage (UFS). In example embodiments, the data storage system 2000 may operate by power supplied from the external host through the connector 2006. The data storage system 2000 may further include a power management integrated circuit (PMIC) distributing the power supplied from the external host to the controller 2002 and the semiconductor package 2003.

The controller 2002 may write data to or read data from the semiconductor device la, and may improve an operating speed of the data storage system 2000.

The DRAM 2004 may be a buffer memory for alleviating a speed difference between the semiconductor device la, which is a data storage space, and the external host. The DRAM 2004 included in the data storage system 2000 may operate as a kind of cache memory, and may provide a space for temporarily storing data in a control operation for the semiconductor device la. When the data storage system 2000 includes the DRAM 2004, the controller 2002 may further include a DRAM controller for controlling the DRAM 2004, in addition to a NAND controller for controlling the semiconductor device la.

The semiconductor device la may include first and second semiconductor packages spaced apart from each other. Each of the first and second semiconductor packages may be a semiconductor package including a plurality of semiconductor chips CH1, CH2, CH3, and CH4.

The package substrate PKS may be a printed circuit board.

In example embodiments, the controller 2002 and the semiconductor chips CH1 to CH4 may be included in one package. For example, the controller 2002 and the semiconductor chips CH1 to CH4 may be mounted on a separate interposer substrate different from the main board 2001, and the controller 2002 and the semiconductor chips CH1 to CH4 may be connected to each other by wirings formed on the interposer substrate.

According to example embodiments, a semiconductor device capable of having an improved degree of integration by including different non-volatile memory structures arranged in a vertical direction may be provided.

According to example embodiments, the different non-volatile memory structures may have different operating speeds. Accordingly, the semiconductor device that has optimized performance may be provided.

According to example embodiments, one of the different non-volatile memory structures may be a stable non-volatile memory, and the other of the different non-volatile memory structures may be a non-volatile memory having a fast operating speed. Accordingly, the semiconductor device that is stable and has optimized performance may be provided.

According to example embodiments, the different non-volatile memory structures may be used for different purposes, and thus, a semiconductor device that is stable and reliable while having an improved overall memory capacity may be provided.

According to example embodiments, various types of data storage devices or data storage systems including the semiconductor device may be provided. For example, a portable data storage device, a vehicle data storage device, or a data storage device of a data center including the semiconductor device may be provided. For example, in a solid state drive (SSD) device, when an ambient temperature is high or a voltage is unstable, information stored in a buffer memory such as a dynamic random access memory (DRAM) may be stored in a non-volatile memory having a fast operating speed among different types of non-volatile memory structures through a controller, such that loss of the information stored in the buffer memory may be limited and/or prevented. Accordingly, a semiconductor device capable of limiting and/or preventing some data from being lost due to an unstable surrounding environment and a system including the same may be provided.

According to example embodiments, in the semiconductor device, a program in which reading/writing is frequently repeated may be stored in a non-volatile memory having a fast operating speed, of the different non-volatile memory structures, and when general data is stored, the general data may be stored in a stabler non-volatile memory, of the different non-volatile memory structures. Accordingly, the semiconductor device that is stable while having a fast data storage speed may be provided.

According to example embodiments, in a vehicle data storage device, information required for autonomous driving that needs to be quickly read and written may be stored in a non-volatile memory having a fast operating speed among the different non-volatile memory structures, and general data such as a black box image may be stored in a non-volatile memory that is stabler or is capable of storing a large-capacity information. Accordingly, a vehicle or a vehicle data storage system capable of realizing stable autonomous driving and storing stable surrounding information may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While example embodiments have been illustrated and described above, it will be apparent to those skilled in the art that modifications and variations could be made without departing from the scope of inventive concepts as defined by the appended claims. Therefore, it is to be understood that the example embodiments described above are illustrative rather than being restrictive in all aspects.

What is claimed is:

1. A semiconductor device comprising:
a first non-volatile memory structure including a first stack structure and a first vertical memory structure, the first stack structure including first conductive lines stacked while being spaced apart from each other in a vertical direction and the first vertical memory structure penetrating through the first stack structure in the vertical direction;
a second non-volatile memory structure including a second stack structure and a second vertical memory structure, the second stack structure including second conductive lines stacked while being spaced apart from each other in the vertical direction and the second vertical memory structure penetrating through the second stack structure in the vertical direction; and
a peripheral circuit structure electrically connected to the first non-volatile memory structure and the second non-volatile memory structure through interconnection structures,
wherein the peripheral circuit structure, the first non-volatile memory structure, and the second non-volatile memory structure overlap each other in the vertical direction,
wherein the first vertical memory structure includes a first data storage structure and the first data storage structure includes a first data storage material layer, and
wherein the second vertical memory structure includes a second data storage structure, the second data storage structure includes a second data storage material layer, and the second data storage material layer is different from the first data storage material layer.

2. The semiconductor device of claim 1, wherein
one of the first data storage material layer and the second data storage material layer includes a charge trap material layer of a flash memory, and
the charge trap material layer is configured to store data by trapping charges.

3. The semiconductor device of claim 2, wherein
an other of the first data storage material layer and the second data storage material layer includes one of a variable resistive material layer configured to store data using a change in resistance according to a change in oxygen vacancy concentration, a phase change material layer configured to store data using a change in resistance according to a phase change, and a ferroelectric material layer configured to store data using a ferroelectric.

4. The semiconductor device of claim 1, wherein
the first non-volatile memory structure is a first memory chip,
the second non-volatile memory structure is a second memory chip, and
the peripheral circuit structure is a peripheral circuit chip.

5. The semiconductor device of claim 4, wherein
the first memory chip is on the peripheral circuit chip,
the second memory chip is on the first memory chip,
the peripheral circuit chip includes first bonding pads,
the first memory chip includes second bonding pads and third bonding pads,
the second memory chip includes fourth bonding pads,
the second bonding pads of the first memory chip are bonded to the first bonding pads of the peripheral circuit chip while being in contact with the first bonding pads of the peripheral circuit chip, and
the third bonding pads of the first memory chip are bonded to the fourth bonding pads of the second memory chip while being in contact with the fourth bonding pads of the second memory chip.

6. The semiconductor device of claim 5, wherein
the interconnection structures include a first connection structure and a second connection structure,
the first connection structure electrically connects the first non-volatile memory structure and the peripheral circuit structure to each other,
the first connection structure includes the first bonding pads and the second bonding pads in contact with each other,
the second connection structure electrically connects the second non-volatile memory structure and the peripheral circuit structure to each other, and
the second connection structure includes the third bonding pads and the fourth bonding pads in contact with each other.

7. The semiconductor device of claim 5, wherein
the first stack structure has a shape in which a width of the first stack structure increases from the peripheral circuit structure toward the second non-volatile memory structure.

8. The semiconductor device of claim 5, wherein
the first data storage material layer is a variable resistive material layer, and
the second data storage material layer is a charge trap material layer.

9. The semiconductor device of claim 4, wherein
the peripheral circuit chip is on the first memory chip,
the second memory chip is on the peripheral circuit chip,
the peripheral circuit chip includes first bonding pads and second bonding pads,
the first memory chip includes third bonding pads,
the second memory chip includes fourth bonding pads,
the first bonding pads of the peripheral circuit chip are bonded to the third bonding pads of the first memory chip while being in contact with the third bonding pads of the first memory chip, and
the second bonding pads of the peripheral circuit chip are bonded to the fourth bonding pads of the second memory chip while being in contact with the fourth bonding pads of the second memory chip.

10. The semiconductor device of claim 1, wherein
the first non-volatile memory structure and the second non-volatile memory structure are a single memory chip, and
the peripheral circuit structure is a peripheral circuit chip.

11. The semiconductor device of claim 10, wherein
the single memory chip is on the peripheral circuit chip,
the peripheral circuit chip includes first bonding pads,
the single memory chip includes second bonding pads, and
the second bonding pads of the single memory chip are bonded to the first bonding pads of the peripheral circuit chip while being in contact with the first bonding pads of the peripheral circuit chip.

12. The semiconductor device of claim 1, wherein
the peripheral circuit structure includes a first peripheral circuit and a second peripheral circuit,
the first peripheral circuit and the first non-volatile memory structure constitute a first semiconductor chip,
the second peripheral circuit and the second non-volatile memory structure constitute a second semiconductor chip,
the first semiconductor chip includes first bonding pads, and
the second semiconductor chip includes second bonding pads bonded to the first bonding pads while being in contact with the first bonding pads.

13. The semiconductor device of claim 1, wherein
the first vertical memory structure and the second vertical memory structure are in contact with each other in the vertical direction.

14. The semiconductor device of claim 1, wherein
the first conductive lines include a first bit line, first word lines stacked on the first bit line while being spaced apart from each other in the vertical direction, and a first common source on the first word lines, and
the second conductive lines include a second bit line, second word lines stacked on the second bit line while being spaced apart from each other in the vertical direction, and a second common source on the second word lines.

15. The semiconductor device of claim 1, wherein
the first conductive lines include a bit line and first word lines stacked on the bit line while being spaced apart from each other in the vertical direction,
the second conductive lines include second word lines and a common source on the second word lines, and
the second word lines are stacked on the first word lines while being spaced apart from each other in the vertical direction.

16. A semiconductor device comprising:
a package substrate;
a semiconductor chip on the package substrate; and
a molded layer covering at least side surfaces of the semiconductor chip on the package substrate,
wherein the semiconductor chip includes a first non-volatile memory structure and a second non-volatile memory structure,
the first non-volatile memory structure includes a first stack structure and first vertical memory structures,
the first stack structure includes first conductive lines stacked while being spaced apart from each other in a vertical direction,
the first vertical memory structure penetrates through the first conductive lines in the vertical direction,
the second non-volatile memory structure includes a second stack structure and second vertical memory structures,
the second stack structure includes second conductive lines stacked while being spaced apart from each other in the vertical direction,
the second vertical memory structure penetrates through the second conductive lines in the vertical direction,
the first stack structure and the second stack structure overlap each other in the vertical direction,
the first vertical memory structure includes a first data storage structure, and
the second vertical memory structure includes a second data storage structure, and
the second data storage structure is different from the first data storage structure.

17. The semiconductor device of claim 16, wherein
the semiconductor chip further includes a peripheral circuit structure, and
the peripheral circuit structure is electrically connected to the first non-volatile memory structure and the second non-volatile memory structure through interconnection structures.

18. The semiconductor device of claim 17, wherein
the semiconductor chip includes at least two chips bonded to each other by intermetallic bonding,
a first chip of the at least two chips includes the peripheral circuit structure, and
a second chip of the at least two chips includes at least one of the first non-volatile memory structure and the second non-volatile memory structure.

19. A data storage system comprising:
a main board;
a semiconductor device on the main board; and
a controller electrically connected to the semiconductor device and on the main board,
wherein
the semiconductor device includes a first non-volatile memory structure, a second, non-volatile memory structure, and a peripheral circuit structure electrically connected to the first non-volatile memory structure and the second non-volatile memory structure through interconnection structures,
the first non-volatile memory structure includes a first stack structure and a first vertical memory structure penetrating through the first stack structure in a vertical direction,
the first stack structure includes first conductive lines stacked while being spaced apart from each other in the vertical direction,
the second non-volatile memory structure includes a second stack structure and a second vertical memory structure penetrating through the second stack structure in the vertical direction, the second stack structure includes second conductive lines stacked while being spaced apart from each other in the vertical direction,
the peripheral circuit structure, the first non-volatile memory structure, and the second non-volatile memory structure overlap each other in the vertical direction,
the first vertical memory structure includes a first data storage structure,
the first data storage structure includes a first data storage material layer,
the second vertical memory structure includes a second data storage structure,
the second data storage structure includes a second data storage material layer, and
the second data storage material layer is different from the first data storage material layer.

20. The data storage system of claim 19, wherein
the first non-volatile memory structure is on the peripheral circuit structure,
the second non-volatile memory structure is on the first non-volatile memory structure,
the first data storage material layer includes one of a variable resistive material layer configured to store data using a change in resistance according to a change in oxygen vacancy concentration, a phase change material layer configured to store data using a change in resistance according to a phase change, and a ferroelectric material layer configured to store data using a ferroelectric,
the second data storage material layer includes a charge trap material layer of a flash memory, and
the charge trap material layer is configured to store data by trapping charges.
